(19) United States
(12) Patent Application Publication
(10) Pub. No.: US 2021/0225869 A1
(43) Pub. Date: Jul. 22, 2021

(54) MEMORY DEVICE AND METHOD OF MANUFACTURING THE SAME

(71) Applicant: SAMSUNG ELECTRONICS CO., LTD., Suwon-si (KR)

(72) Inventor: Sejie Takaki, Suwon-si (KR)

(73) Assignee: SAMSUNG ELECTRONICS CO., LTD., Suwon-si (KR)

(21) Appl. No.: 17/021,627

(22) Filed: Sep. 15, 2020

(30) Foreign Application Priority Data
Jan. 20, 2020 (KR) 10-2020-0007271

(51) Int. Cl. H01L 27/11582; H01L 21/311; H01L 27/11573

(52) U.S. Cl. CPC H01L 27/11582; H01L 27/11573; H01L 21/31105

(57) ABSTRACT

A memory device includes a substrate, a stacked structure, channel layers, and separation layers. The substrate includes a first layer, a second layer on the first layer, and a third layer on the second layer/ The stacked structure including electrode layers stacked on the substrate. The channel layers extend in a direction perpendicular to an upper surface of the substrate, to penetrate through the stacked structure and to contact with the second layer in a direction horizontal to the upper surface of the substrate. The separation layers divide the stacked structure into unit structures. A first boundary between the first layer and the second layer below one or more of the separation layers is disposed to be lower than a second boundary between the first layer and the second layer that is located between an adjacent two channel layers.

### CROSS-REFERENCE TO RELATED APPLICATION(S)

This application claims priority from Korean Patent Application No. 10-2020-0007271 filed on Jan. 20, 2020 in the Korean Intellectual Property Office, the disclosure of which is herein incorporated by reference in its entirety.

### BACKGROUND

### 1. Field

The present disclosure relates to a memory device and a method of manufacturing the same.

### 2. Description of Related Art

A memory device may provide a function of writing or erasing data, and a function of reading written data. Memory devices may be classified into non-volatile memory devices and volatile memory devices. Nonvolatile memory devices may retain their written data even when power supplies thereof are interrupted. Data storage capacity required for a memory device continues to grow. Accordingly, a variety of attempts have been made to increase integration density of a memory device.

### SUMMARY

It is an aspect to provide a memory device having improved reliability.

According to an aspect of an example embodiment, there is provided a memory device comprising a substrate including a first layer, a second layer on the first layer, and a third layer on the second layer; a stacked structure including a plurality of electrode layers stacked on the substrate; a plurality of channel layers extending in a direction perpendicular to an upper surface of the substrate, to penetrate through the stacked structure and to contact with the second layer in a direction horizontal to the upper surface of the substrate; and a plurality of separation layers dividing the stacked structure into unit structures, wherein a first boundary between the first layer and the second layer below at least one of the plurality of separation layers is disposed to be lower than a second boundary between the first layer and the second layer that is located between an adjacent two channel layers of the plurality of channel layers.

According to another aspect of an example embodiment, there is provided a memory device comprising a substrate including a first layer, a second layer, and a third layer sequentially stacked; a plurality of channel layers extending in a first direction perpendicular to an upper surface of the substrate, extending to the first layer through the second layer and the third layer, and being in contact with the second layer in a direction parallel to the upper surface of the substrate; a plurality of electrode layers stacked on the upper surface of the substrate; and a plurality of separation layers extending between the plurality of channel layers in the first direction and extending in a second direction parallel to the upper surface of the substrate, wherein a portion of a lower surface of the second layer, being in contact with the first layer, is disposed to be lower than lower surfaces of the plurality of channel layers, and a remaining portion of the lower surface of the second layer is disposed to be higher than the lower surfaces of the plurality of channel layers.

According to another aspect of an example embodiment, there is provided a memory device comprising a peripheral circuit region including a lower substrate, a plurality of circuit elements disposed on the lower substrate, and a lower interlayer insulating layer covering the plurality of circuit elements; and a cell region including an upper substrate disposed on the lower interlayer insulating layer, a plurality of electrode layers stacked in a first direction perpendicular to an upper surface of the upper substrate, a plurality of channel layers extending in the first direction to penetrate through the plurality of electrode layers and electrically connected to the upper substrate, and a separation layer dividing the plurality of electrode layers, wherein the upper substrate includes a first layer, a second layer that is stacked on the first layer and that is in contact with the plurality of channel layers in a direction parallel to an upper surface of the first layer, and a third layer that is stacked on the second layer, and the second layer includes a first region below the separation layer and a second region between the plurality of channel layers, and a thickness of the first region is greater than a thickness of the second region.

According to another aspect of an example embodiment, there is provided a method of manufacturing a memory device, the method comprising forming a first layer on a base layer, the base layer including an insulating material, the first layer being formed of a first material different from the insulating material of the base layer; removing at least a portion of the first layer to form a plurality of trenches; sequentially forming a lower sacrificial layer, an intermediate sacrificial layer, an upper sacrificial layer, and a stopper layer on the first layer to fill the plurality of trenches with the intermediate sacrificial layer; alternately stacking a plurality of electrode sacrificial layers and a plurality of insulating layers on the stopper layer;

forming a plurality of channel structures that extend to the first layer through the plurality of electrode sacrificial layers and through the plurality of insulating layers, the plurality of channel structures extending in a first direction perpendicular to an upper surface of the base layer; exposing the intermediate sacrificial layer by forming a plurality of separation trenches that extend respectively from upper portions of the plurality of trenches in the first direction and that extend in a second direction parallel to the upper surface of the base layer; removing the lower sacrificial layer, the intermediate sacrificial layer, and the upper sacrificial layer through the plurality of separation trenches; and filling a region, in which the lower sacrificial layer, the intermediate sacrificial layer, and the upper sacrificial layer are removed, with a second material different from the insulating material of the base layer.

### BRIEF DESCRIPTION OF DRAWINGS

The above and other aspects will be more clearly understood from the following detailed description, taken in conjunction with the accompanying drawings, in which:

FIGS. 1 and 2 are schematic block diagrams of a memory device according to an example embodiment;

FIG. 3 is a schematic circuit diagram illustrating a memory block of a memory cell array of a memory device according to an example embodiment;

FIG. 4 is a plan view illustrating a portion of a memory device according to an example embodiment;

FIG. 5 is a cross-sectional view taken along a line I-I′ in FIG. 4;

FIGS. 6 to 9 are enlarged views of a portion ‘A’ in FIG. 5, according to various example embodiments;

FIG. 10 is an enlarged view of a portion B in FIG. 5;

FIG. 11 is a cross-sectional view taken along a line II-IF in FIG. 4;

FIG. 12 is a cross-sectional view taken along a line in FIG. 4;

FIGS. 13 and 14 illustrate memory devices according to example embodiments, respectively;

FIG. 15 is a plan view illustrating a portion of a memory device according to an example embodiment;

FIG. 16 is a cross-sectional view taken along a line IV-IV′ in FIG. 14;

FIG. 17 is a cross-sectional view taken along a line V-V′ in FIG. 14;

FIG. 18 is a plan view illustrating a portion of a memory device according to an example embodiment;

FIG. 19 is a cross-sectional view taken along a line VI-VI′ in FIG. 18;

FIG. 20 is a cross-sectional view taken along a line VII-VII′ in FIG. 18;

FIGS. 21 to 34 illustrate a method of manufacturing a memory device according to an example embodiment;

FIGS. 35 to 41 illustrate a method of manufacturing a memory device according to an example embodiment; and

FIG. 42 is a schematic block diagram of an electronic device including a memory device according to an example embodiment.

### DETAILED DESCRIPTION

Hereinafter, example embodiments will be described with reference to the accompanying drawings.

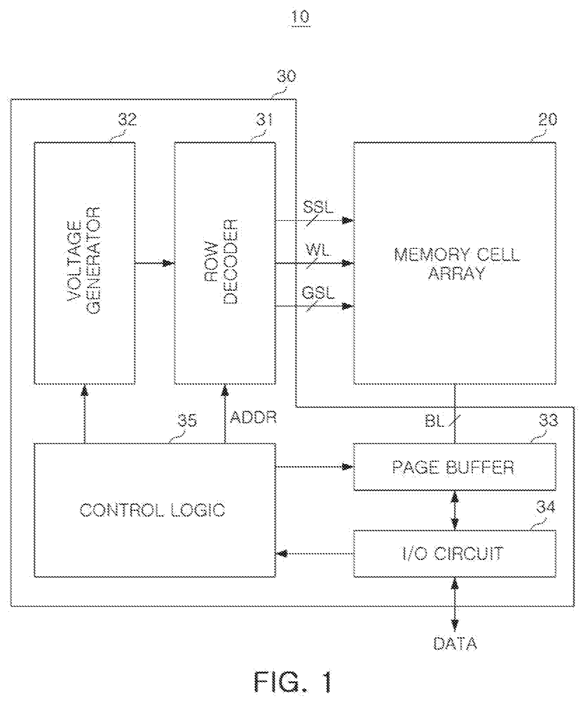

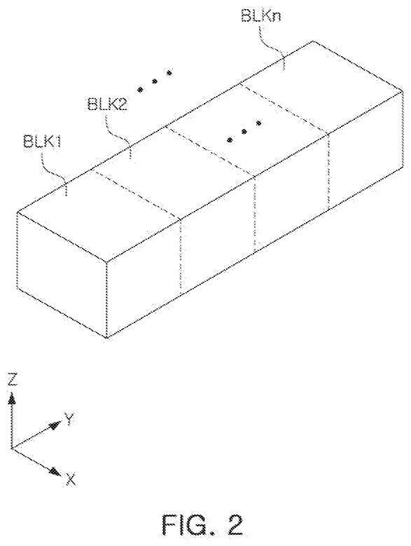

FIGS. 1 and 2 are schematic block diagrams of a memory device according to an example embodiment.

Referring to FIG. 1, a memory device 10 may include a memory cell array 20 and a peripheral circuit 30. The peripheral circuit 30 may include a row decoder 31, a voltage generator 32, a page buffer 33, an input/output (I/O) circuit 34, control logic 35, and the like.

The memory cell array 20 may include a plurality of memory cells, and the memory cell array 20 may be divided into a plurality of memory blocks. The plurality of memory cells may be connected to the row decoder 31 through a string select line SSL, wordlines WL, a ground select line GSL, and the like, and may be connected to the page buffer 33 through bitlines BL. In example embodiments, memory cells arranged along the same row may be connected to the same wordline WL, and memory cells arranged along the same column may be connected to the same bitline BL.

The row decoder 31 may decode address data ADDR, input from the control logic 35 or the like, to generate and transmit voltages for driving the wordline WL. The row decoder 31 may input a wordline voltage, generated by the voltage generator 32 in response to control of the control logic 35, to the wordlines WL. As an example, the row decoder 31 may be connected to the wordlines WL through pass elements, and may input the wordline voltage to the wordlines WL when the pass elements are turned on.

The page buffer 33 may be connected to the memory cell array 20 through bitlines BL, and may read information stored in memory cells or write data to memory cells. The page buffer 33 may include a column decoder and a sense amplifier. The column decoder may select at least a portion of bitlines BL of the memory cell array 20, and the sense amplifier may read data of a memory cell connected to the bitline selected by the column decoder during a read operation.

The I/O circuit 34 may receive and transmit data to the page buffer 33 during a program operation, and may output data, read from the memory cell array by the page buffer 33, to an external entity that is external to the memory device 10 during a read operation. The I/O circuit 34 may transmit an address or an instruction, received from an external memory controller that is external to the memory device 10, to the control logic 35.

The control logic 35 may control operations of the row decoder 31, the voltage generator 32, the page buffer 33, and the like. In example embodiments, the control logic 35 may operate according to an external voltage and a control signal transmitted from an external memory controller that is external to the memory device 10, or the like.

The voltage generator 32 may generate control voltages for the operation of the memory device 10, such as a program voltage, a read voltage, an erase voltage, a pass voltage, and the like, using an externally input power supply voltage. A voltage, output from the voltage generator 32, may be supplied to the peripheral circuit 30 or may be input to the memory cell array 20 through the row decoder 31, or the like.

As an example, a program voltage may be input to a selected wordline, connected to a selected memory cell to be written, in a program operation. A pass voltage, lower than the program voltage, may be input to unselected wordlines connected to unselected memory cells included in a single memory cell string to share a channel layer with the selected memory cell.

In example embodiments, in a read operation, a read voltage may be input to a selected wordline, connected to a selected memory cell to read data, and a pass voltage may be input to unselected wordlines connected to unselected memory cells sharing a channel layer with a selected memory cell. In an example embodiment in which each of the memory cells stores data having a plurality of bits, the row decoder 31 may input a plurality of read voltages, having different sizes to each other, to a selected wordline.

Referring to FIG. 2, the memory cell array 20 may include a plurality of memory blocks BLK1 to BLKn. Each of the memory blocks BLK1 to BLKn may include wordlines, stacked in a first direction (a Z-axis direction), and channel layers extending in the first direction. The wordlines may extend on a plane defined by a second direction (an X-axis direction) and a third direction (a Y-axis direction).

Wordlines and channel structures may provide three-dimensionally arranged memory cells. Each of the memory blocks BLK1 to BLKn may include bitlines extending in the second direction or the third direction and connected to the channel layers. As an example, in the memory cell array 20, the memory blocks BK1 to BKn may be arranged in the second direction and the third direction.

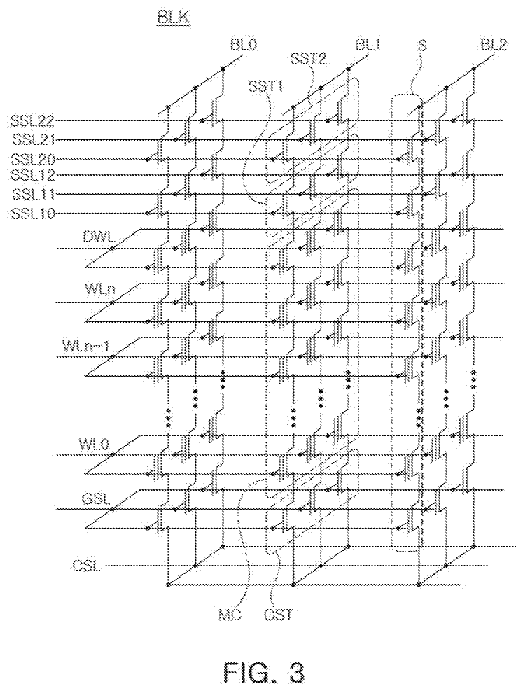

FIG. 3 is a schematic circuit diagram illustrating a memory block of a memory cell array of a memory device, according to an example embodiment.

Referring to FIG. 3, a single memory block BLK may include a plurality of memory cell strings S, and at least a portion of the memory cell strings S may share wordlines WL1 to WLn and bitlines BL1 to BL3.

Each of the memory cell strings S may include a plurality of memory cells MC connected between the first and second string select transistors SST1 and SST2 and the ground select transistor GST. The first and second string select transistors SST1 and SST2 are connected to each other in series, and the overlying second string select transistor SST2 may be connected to one of the bitlines BL1 to BL2. A ground select transistor GST may be connected to a common source line CSL.

The plurality of memory cells MC may be connected between the first and second string select transistors SST1 and SST2 and the ground select transistor GST to each other in series. According to example embodiments, the number of string select transistors SST1 and SST2 and the ground select transistor GST may be variously changed, and each of the memory cell strings S may further include at least one dummy memory cell.

Gate electrodes of the plurality of memory cells MC may be connected to the wordlines WL0 to WLn. A gate electrode of the ground select transistor GST may be connected to the ground select line GSL, and gate electrodes of the first and second string select transistors SST1 and SST2 may be connected to the string select lines SSL11 to SSL23.

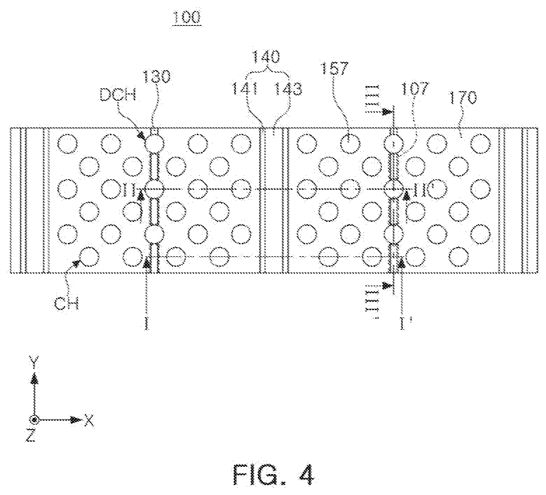

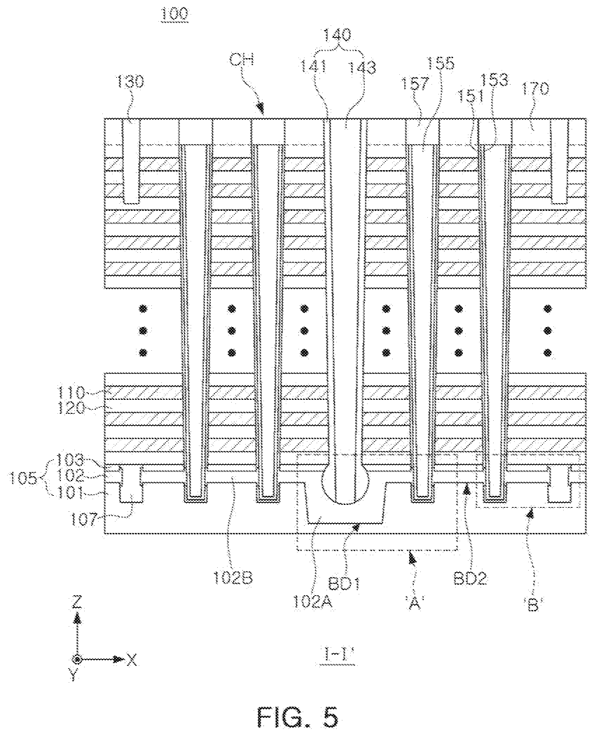

FIG. 4 is a plan view illustrating a portion of a memory device according to an example embodiment. FIG. 5 is a cross-sectional view taken along a line I-I′ in FIG. 4.

Referring to FIGS. 4 and 5, a memory device 100 according to an example embodiment may include a substrate 105, a stacked structure including a plurality of electrode layers 110 and a plurality of insulating layers 120 alternately stacked on the substrate 105, a plurality of channel structures CH extending in the first direction (a Z-axis direction) perpendicular to an upper surface of the substrate 105, a plurality of separation layers 140 dividing the stacked structure into unit structures, an interlayer insulating layer 170 covering the stacked structure, and the like.

The substrate 105 may include a first layer 101, a second layer 102 on the first layer 101, a third layer 103 on the second layer 102, and the like. The third layer 103 may have a smaller thickness in the first direction than a thickness of the first layer 101 and a smaller thickness than a thickness of the second layer 102 in the first direction. In example embodiments, the first layer 101 and the second layer 102 may include a semiconductor material doped with impurities of the same conductivity type. For example, the first layer 101 and the second layer 102 may include polysilicon doped with n-type impurities. The third layer 103 may be doped with impurities of the same conductivity type as the first layer 101 and the second layer 102, or may be formed of a semiconductor material, not including impurities. An impurity concentration of the third layer 103 may be lower than an impurity concentration of the first layer 101 and/or an impurity concentration of the second layer 102.

In example embodiments, the memory device 100 may include a plurality of support patterns 107. The support patterns 107 may be formed of an insulating material, for example, a silicon oxide, a silicon nitride, or the like. The support patterns 107 may extend from an upper surface of the third layer 103 to the first layer 101. Referring to FIG. 5, the support patterns 107 may extend from an upper surface of the third layer 103, for example, from a boundary surface between a stacked structure and the third layer 103, and a lower surface of the support patterns 107 may be embedded in the first layer 101. A thickness of the support patterns 107 may be greater than a sum of thicknesses of the second layer 102 and the third layer 103. According to some example embodiments, an upper surface of at least a portion of the support patterns 107 may be disposed to be higher than an upper surface of the third layer 103.

In the example embodiment illustrated in FIGS. 4 and 5, the support patterns 107 may be disposed to be separated from each other in a second direction (an X-axis direction) and a third direction (a Y-axis direction) (as best seen in FIG. 4). As an example, the support patterns 107 may be disposed respective below a plurality of upper separation layers 130 that divide at least one of the electrode layers 110. Each of the upper separation layers 130 may separate at least one of the electrode layers 110 between the separation layers 140 adjacent to each other in the second direction (as best seen in FIG. 4). As an example, the electrode layers 110 separated by the upper separation layers 130 may be a string select lines.

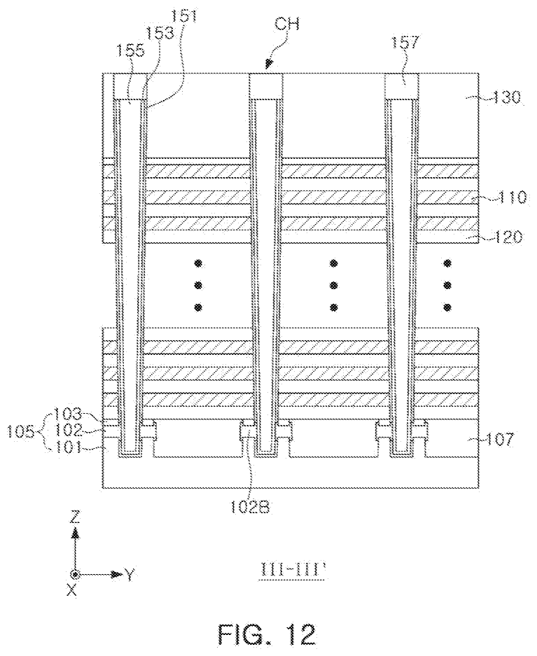

Two or more of the support patterns 107, separated in a third direction, may be disposed below one of the upper separation layers 130 (as best seen in FIG. 12). However, this is an example embodiment, and the arrangement and shape of the support patterns 107 may be variously changed. As an example, the support patterns 107 may be variously arranged so as not to overlap channel structures CH on a plane defined by the second direction and the third direction.

The electrode layers 110 may be formed of a conductive material, for example, a metal material such as tungsten, and the insulating layers 120 may be formed of an insulating material such as a silicon oxide. Each of the channel structures CH may include an electrode insulating layer 151, a channel layer 153, a buried insulating layer 155, a channel connection layer 157, and the like. The electrode insulating layer 151 may include a plurality of layers, for example, a tunneling layer, a charge storage layer, a blocking layer, and the like. The channel layer 153 may be formed of a semiconductor material. As an example, the channel layer 153 may be formed of polysilicon doped with p-type impurities. The channel connection layer 157 may be formed of a semiconductor material, for example, polysilicon doped with n-type impurities.

The electrode insulating layer 151 may be formed to surround an external surface of the channel layer 153, and may be disposed between the electrode layers 110 and the channel layer 153. The electrode insulating layer 151 may be omitted in a region adjacent to the second layer 102 of the substrate 105. Therefore, as illustrated in FIG. 5, the channel layers 153 may be electrically connected to each other through the second layer 102. The second layer 102 may extend in the second direction and the third direction to connect the channel layers 153 to each other. As an example, the second layer 102 may be in direct contact with the channel layers 153 and may be formed to penetrate into at least one side surface of the support patterns 107.

Each of the separation layers 140 may include a side spacer 141, a separation conductive layer 143, and the like. The separation conductive layer 143 may include a conductive material and may be directly connected to the substrate 105. As an example, the separation conductive layer 143 may be in contact with the second layer 102. In example embodiments, at least one of the separation layers 140 may have a curved region at a lower portion thereof as illustrated, by way of example, in FIG. 5. In the example embodiment illustrated in FIG. 5, the separation conductive layer 143 may have a tapered shape, in which a width thereof in the second direction is decreased in a direction toward the second layer 102 (i.e., as the separation conductive layer 143 becomes closer to the second layer 102, the width thereof may decrease), and may surround the separation conductive layer 143 while a width of the side spacer 141 is increased and decreased in the curved region.

In example embodiments, the second layer 102 may have a relatively greater thickness around the separation layers 140. Referring to FIG. 5, the second layer 102 may include a first region 102A and a second region 102B, and the first region 102A connected to the separation layers 140 may have a thickness greater than a thickness of the second region 102B between the channel layers 153. Due to a difference in thickness between the first region 102A and the second region 102B, a thickness of the first layer 101 below the separation layers 140 may be smaller than a thickness of the first layer 101 below the channel layers 153.

Under a condition in which the thickness of the first region 102A is greater than the thickness of the second region 102B, the second layer 102 of the substrate 105 may have various shapes. As an example, as illustrated in FIG. 5, a lower surface of the second layer 102 in the first region 102A may be formed to be lower than the lower surface of the second layer 102 in the second region 102B, and thus, the first region 102A may have a greater thickness than the second region 102B. Unlike what is illustrated in FIG. 5, in some example embodiments, an upper surface of the second layer 102 in the first region 102A may be disposed to be lower than the upper surface of the second layer 102 in the second region 102B. Returning to FIG. 5, due to the first region 102A having a relatively high thickness below the separation layers 140, the channel layers 153 disposed on opposite sides of at least one of the separation layers 140 may be in contact with the second layer 102.

Referring to FIG. 5, a boundary between the first layer 101 and the second layer 102 may include a first boundary DB1 below the separation layers 140 and a second boundary BD2 between the channel layers 153. Since the second layer 102 has a relatively high thickness below the separation layers 140, the first boundary BD1 may be disposed to be lower than the second boundary BD2. For example, the first boundary BD1 may be disposed to be closer to a lower surface of the first layer 101 than the second boundary BD2. In addition, the first boundary BD1 may be disposed to be lower than a lower surface of the support patterns 107.

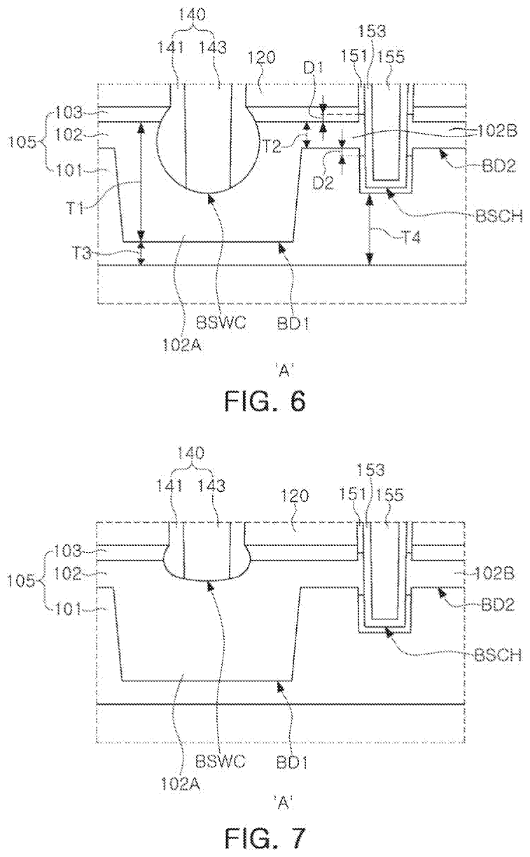

FIGS. 6 to 9 are enlarged views of a portion ‘A’ in FIG. 5, according to various example embodiments.

Referring to FIG. 6, the second layer 102 includes a first region 102A directly contacting the separation layers 140 and a second region 102B, disposed to be in direct contact with the separation layers 140 and disposed to be in direct contact with the channel layers 153. The first region 102A may have a first thickness T1 greater than a second thickness T2 of the second region 102B.

Accordingly, a first boundary BD1 between the first layer 101 and the second layer 102 may be disposed to be lower than a second boundary BD2 between the first layer 101 and the second layer 102 in the first direction (Z-axis direction). The first boundary BD1 may be disposed to be closer to a lower surface of the first layer 101 than the second boundary BD2.

Since the second layer 102 has a relatively high thickness around the separation layers 140, a thickness difference may also occur in the first layer 101. As an example, as illustrated in FIG. 6, the first layer 101 has a third thickness T3 below the separation layers 140 and a fourth thickness T4 below the channel layers 153, and the third thickness T3 may be less than the fourth thickness T4. In some example embodiments, the third thickness T3 may be greater than a thickness of the third layer 103.

As described above, the second layer 102 may be in contact with side surfaces of the channel layers 153. Therefore, as illustrated in FIG. 6, the electrode insulating layer 151 may have regions that are vertically separated in a first direction by the second layer 102. On the side surfaces of the channel layers 153, the second layer 102 may extend by a first length D1 and a second length D2 in the first direction. The first length D1 and the second length D2 may be the same as each other or different from each other.

In the example embodiment illustrated in FIG. 6, at least a portion of the separation layers 140 may be disposed in the first region 102A, and a lower surface BSWC of the separation conductive layer 143 may be disposed to be lower than the second boundary BD2. In addition, in the example embodiment illustrated in FIG. 6, a lower surface BSCH of the channel layers 153 is illustrated as being disposed at substantially the same height as the lower surface BSWC of the separation conductive layer 143. However, the present disclosure is not limited thereto. As an example, the lower surface BSWC of the separation conductive layer 143 may be disposed above or below the lower surface BSCH of the channel layers 153. Also, a portion of the lower surface of the second layer 102 in the second region 102B may be lower than the lower surfaces BSCH of the channel layers 153.

Referring to FIG. 7, in some example embodiments, lower surfaces BSWC of the separation layers 140 may be disposed to be higher than the second boundary BD2. For example, the lower surfaces BSWC of the separation layers 140 disposed to be in contact with the first region 102A may be disposed to be higher than the second boundary BD2, which is a lower surface of the second layer 102 in the second region 102B, in the first direction (the Z-axis direction). Therefore, in an example embodiment illustrated in FIG. 7, the lower surfaces BSWC of the separation layers 140 may be disposed to be higher than the lower surfaces BSCH of the channel layers 153.

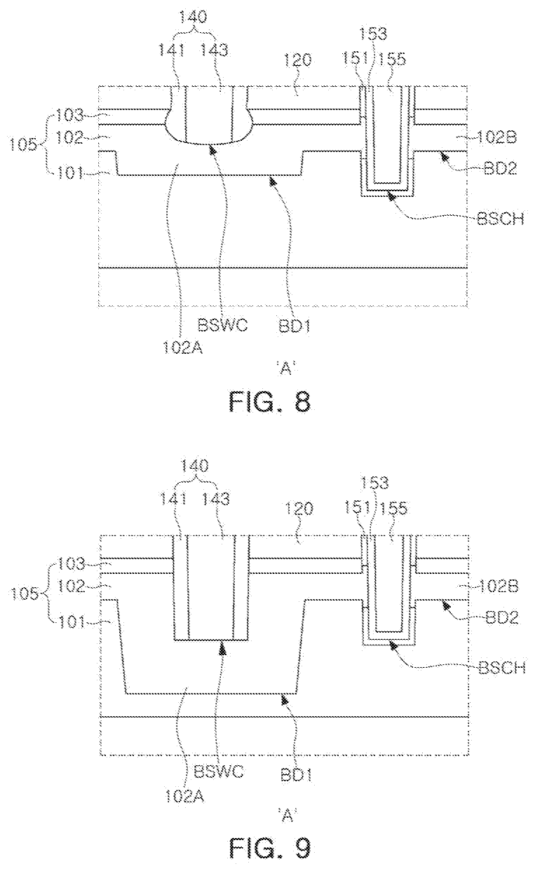

Referring to FIG. 8, a first boundary BD1, which is a lower surface of the second layer 102 in the first region 102A, may be disposed between the second boundary BD2 and lower surfaces BSCH of the channel layers 153. In an example embodiment illustrated in FIG. 8, the first boundary BD1 may be disposed to be higher than the lower surfaces BSCH of the channel layers 153. In other words, a portion of the lower surface of the second layer 102 in the second region 102B may be higher than the lower surfaces BSCH of the channel layers 153.

Referring to FIG. 9, in a region in which the separation layers 140 and the substrate 105 are in contact with each other, side surfaces of the separation layers 140 may not have a protruding shape (i.e., curved region). In the example embodiment illustrated in FIG. 9, the lower surfaces BSWC of the separation layers 140 are illustrated as being disposed to be lower than the second boundary BD2. However, the present disclosure is not limited thereto. As an example, in some example embodiments, the lower surface BSWC of the separation layers 140 may be disposed to be higher than the second boundary BD2 in the first direction (Z-axis direction). The lower surfaces BSWC of the separation layers 140 may be disposed to be higher or lower than the lower surfaces BSCH of the channel layers 153. In addition, in the example embodiment illustrated in FIG. 9, the first boundary BD1 may be disposed between the second boundary BD2 and the lower surfaces BSCH of the channel layers 153.

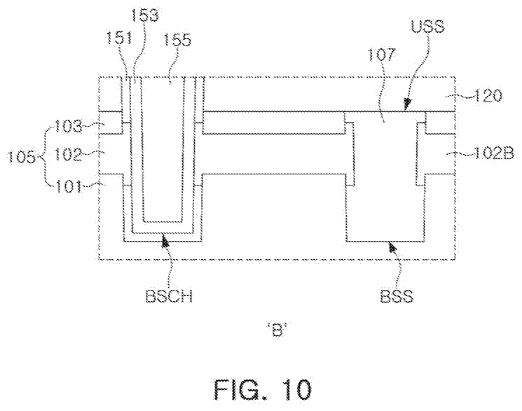

FIG. 10 is an enlarged view of a portion B in FIG. 5.

Referring to FIG. 10, at least one of the channel layers 153 may be adjacent to support patterns 107 in the second direction (the X-axis direction). The support patterns 107 are structures for preventing a stacked structure, formed on the third layer 103, from leaning in a process of manufacturing the memory device 100, and may be formed of an insulating material. In example embodiments, an empty space may be present between the first layer 101 and the third layer 103 during the process of manufacturing the memory device 100, and the support patterns 107 may prevent the stacked structure and/or the substrate 105 from leaning when the empty space is formed.

The support patterns 107 may connect the first layer 101 and the third layer 103 to each other. Therefore, lower surface BSS of the support patterns 107 may be in direct contact with the first layer 101. In the example embodiment illustrated in FIG. 10, the lower surfaces BSS of the support patterns 107 are illustrated as being disposed to be lower than the lower surfaces BSCH of the channel layers 153 and as being disposed at substantially the same height as the lower surface of the channel structures CH. However, the present disclosure is not limited thereto. The lower surfaces BSS of the support patterns 107 may be in direct contact with the first layer 101, and locations thereof may be variously determined.

In the example embodiment illustrated in FIG. 10, the upper surface USS of the support patterns 107 may be coplanar with an upper surface of the third layer 103. Therefore, the upper surfaces USS of the support patterns 107 may be in direct contact with an insulating layer 120 disposed on a lowermost end of the stacked structure. However, according to example embodiments, the support patterns 107 may be embedded in the third layer 103 so as not to be exposed to an external entity. For example, the third layer 103 may be present between the support patterns 107 and the lowermost insulating layer 120.

Referring to FIG. 10, at least one of the support patterns 107 may include a first support region and a second support region having different widths to each other. As an example, the first support region may be in contact with the first layer 101, and the second support region may be in contact with the second layer 102. A portion of the second support region may be removed during a manufacturing process, and thus, the second support region may have a narrower width than the first support region.

In addition, at least one of the support patterns 107 may include a third support region formed to be in contact with the third layer 103. The third support region may have a greater width than the second support region. In addition, the support patterns 107 may be narrowed in a direction toward the first layer 101, and the third support region may have a greater width than the first support region.

The shape and arrangement of the support patterns 107 may be variously changed. According to some example embodiments, the support patterns 107 may be disposed below the separation layers 140. When the support patterns 107 are disposed below the separation layers 140, the support patterns 107 are separated from each other in a third direction (an X-axis direction), in which the separation layers 140 extend, to perform a process of forming the second layer 102 of the substrate 105.

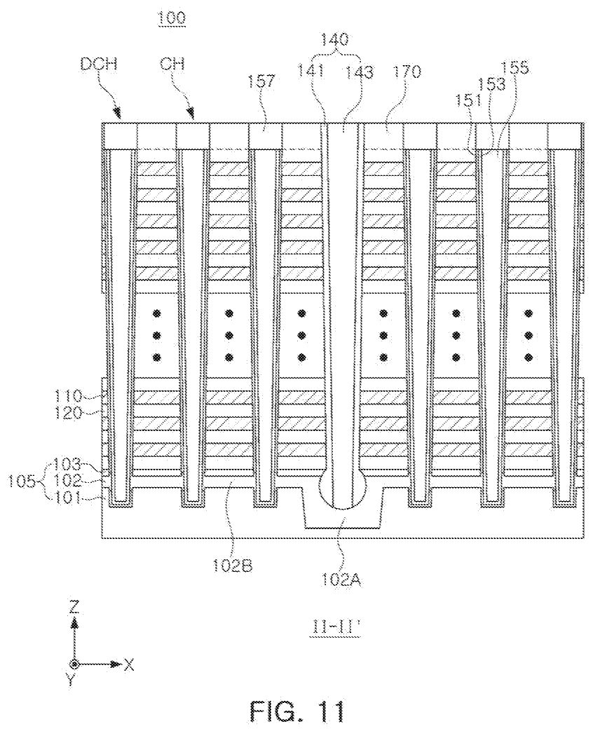

FIG. 11 is a cross-sectional view taken along a line II-IF in FIG. 4, and FIG. 12 is a cross-sectional view taken along a line in FIG. 4.

Referring to FIG. 11, the memory device 100 may further include dummy channel structures DCH having substantially the same structure as the channel structures CH. Similarly to the channel structures CH, the dummy channel structures DCH may include an electrode insulating layer 151, a channel layer 153, a buried insulating layer 155, and a channel connection layer 157. However, the dummy channel structures DCH may not be electrically connected to bitlines. Accordingly, the memory cells provided by the dummy channel structures DCH and the electrode layers 110 may be dummy memory cells in which a program operation or a read operation is not actually performed.

Referring to FIG. 12, support patterns 107 disposed in the same location in the second direction (the X-axis direction) may be separated from each other in the third direction (the Y-axis direction). The support patterns 107 may be disposed below one of the upper separation layers 130. The upper separation layers 130 may extend in the third direction, and the electrode layers 120 providing a string select line may be divided into a plurality of regions by the upper separation layers 130.

Dummy channel structures DCH may be disposed between the support patterns 107 in the third direction. Referring to the plan view of FIG. 4, channel structures CH may be disposed between the support patterns 107 in the second direction. For example, the support patterns 107 may be disposed so as not to overlap the channel structures CH and the dummy channel structures DCH.

However, according to some example embodiments, the support patterns 107 may overlap the dummy channel structures DCH on a plane. In this case, at least one of the support patterns 107 may be in contact with the dummy channel structure DCH. At least one of the support patterns 107 may be penetrated through by the dummy channel structure DCH. A channel layer 153 of the dummy channel structure DCH, disposed to be in contact with at least one of the support patterns 107, may not be in contact with the second layer 102 of the substrate 105.

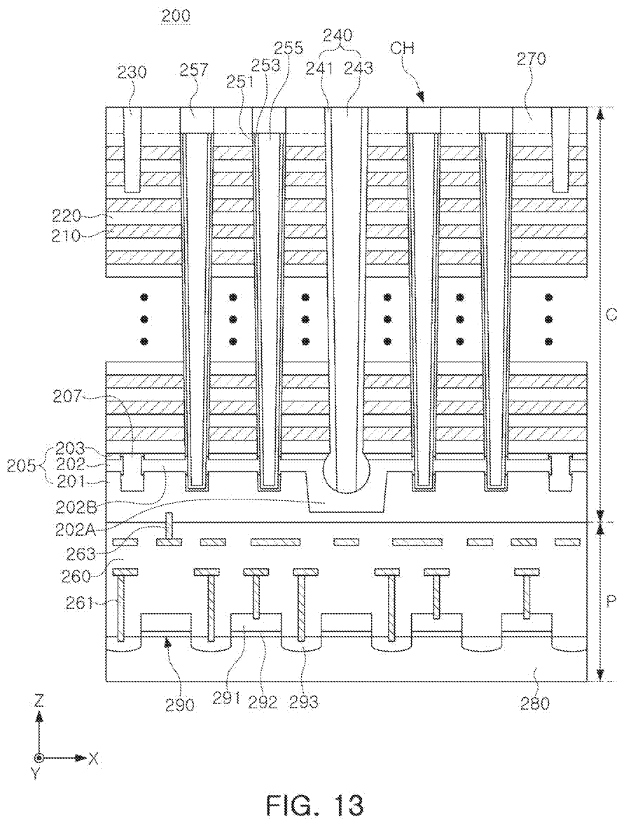

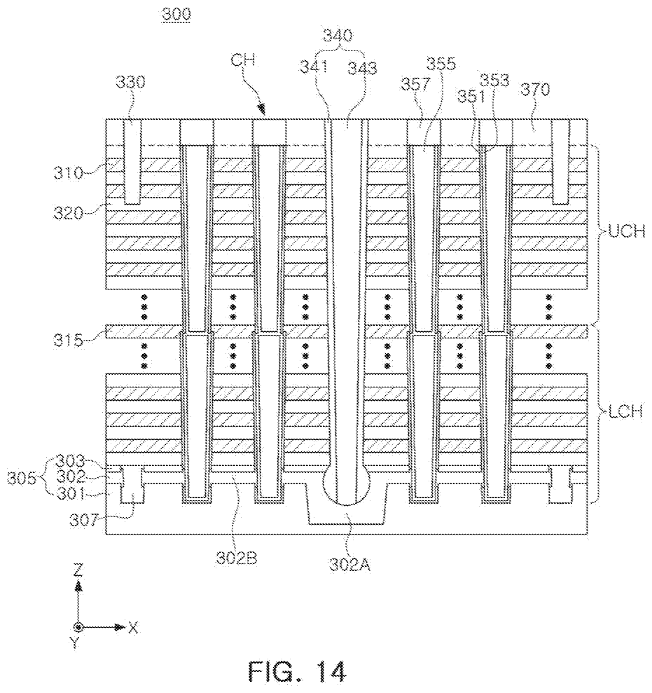

FIGS. 13 and 14 illustrate memory devices according to example embodiments, respectively.

Referring to FIG. 13, a memory device 200 may include a peripheral circuit region P and a cell region C. The peripheral circuit region P and the cell region C may be stacked in a first direction (a Z-axis direction). As an example, the cell region C may be disposed on the peripheral circuit region P. The cell region C may include a plurality of memory cells, and wordlines and bitlines connected to the memory cells, and the peripheral circuit region P may include circuits for driving memory cells.

The peripheral circuit region P may include a lower substrate 280, a plurality of circuit elements 290 formed on the lower substrate 280, a lower interlayer insulating layer 260 covering the circuit elements 290 on the lower substrate 280, and the like. The circuit elements 290 may provide a row decoder, a page buffer, a power generator, a control logic, and the like. The circuit elements 290 may include a transistor having a gate electrode 291, an electrode insulating layer 292, and an active region 293. The circuit elements 290 may be connected to the metal wirings 261 embedded in the lower interlayer insulating layer 260.

The lower interlayer insulating layer 260 may be formed of an insulating material such as a silicon oxide, and may be provided as a base layer for forming the upper substrate 205. As an example, the upper substrate 205 may be formed of polysilicon on the lower interlayer insulating layer 260, and the upper substrate 205 may include a first layer 201, a second layer 202, a third layer 203, and the like. The third layer 203 may have a thickness smaller than a thickness of each of the first layer 201 and the second layer 202.

The first layer 201 and the second layer 202 may be formed of a material different from a material of a base layer. As an example, the first layer 201 may be formed of a first material different from the material of the base layer, and the second layer 202 may be formed of a second material different from the material of the base layer. In example embodiments, the first material and the second material may be semiconductor materials, and may be polysilicon doped with conductive impurities, for example, n-type impurities. The second layer 202 may include a first region 202A, disposed below separation layers 240 and having a relatively high thickness, and a second region disposed between channel structures CH and having a relatively small thickness.

Among metal wirings 261, at least one metal wiring 261 may be connected to the upper substrate 205 by a source contact 263. During an operation of the memory device 200, a source voltage may be input to the upper substrate 205 through the source contact 263. The source contact 263 may be electrically connected to at least one of the first layer 201 and the second layer 202.

A stacked structure, including electrode layers 210, insulating layers 220, and an upper interlayer insulating layer 270, may be disposed on the upper substrate 205, and channel structures CH may be formed to be connected to the upper substrate 205 through the stacked structure. Each of the channel structures CH may include an electrode insulating layer 251, a channel layer 253, a buried insulating layer 255, a channel connection layer 257, and the like. The stacked structure may be divided into unit structures by the separation layers 240. For example, each of the unit structures may be a single memory block. The stacked structure and the channel structures CH may be understood with reference to the description of the example embodiment illustrated in FIG. 5.

The channel structures CH extend to the first layer 201 of the upper substrate 205, and the channel layers 253 may be in direct contact with the second layer 202. Accordingly, the channel layers 253 of the channel structures CH may be electrically connected to each other through the second layer 202. The second layer 202 may include a first region 202A and a second region 202B, and the channel layers 253 may be in direct contact with the second region 202B. The first region 202A may be disposed below the separation layers 240 and may have a relatively larger thickness than each of the second regions 202B.

A portion of the electrode layers 210, providing a string select line, may be divided into a plurality of regions by the upper separation layers 230. Support patterns 207 may be disposed respectively below the upper separation layers 230, and may extend between the first layer 201 and the third layer 203 of the substrate 205. For example, the support patterns 207 may be in contact with the first layer 201 and the third layer 203 through the second layer 202. The support patterns 207 may be disposed so as not to overlap the channel structures CH.

Referring to FIG. 14, a memory device 300 may include a substrate 305 having a first layer 301, a second layer 302, and a third layer 303 sequentially stacked. Electrode layers 310, insulating layers 320, channel structures CH, upper separation layers 330, separation layers 340, interlayer insulation layer 370, and the like, may be provided on the substrate 305. Support patterns 307 may be disposed below the upper separation layers 330. The second layer 302 may include a first region 302A, disposed below the separation layers 340 and having a relatively high thickness, and a second region disposed between the channel structures CH and having a relatively small thickness.

In the example embodiment illustrated in FIG. 14, each of the channel structures CH may include a lower channel structure LCH and an upper channel structure UCH. The lower channel structure LCH may extend from the substrate 305, and the upper channel structure UCH may extend from the lower channel structure LCH to the interlayer insulating layer 370. The electrode insulating layers 351 and the channel layers 353 may be connected to each other on a boundary between the upper channel structure UCH and the lower channel structure LCH.

A dummy electrode layer 315 may be disposed on the boundary between the upper channel structure UCH and the lower channel structure LCH. Characteristics of the electrode insulating layers 351 and the channel layers 353 may be deteriorated on the boundary between the upper channel structure UCH and the lower channel structure LCH. Accordingly, the dummy electrode layer 315 may be disposed on the boundary between the upper channel structure UCH and the lower channel structure LCH, and the dummy electrode layer 315 may provide a dummy wordline connected to a dummy memory cell. In the dummy memory cell, a programming operation, a read operation, or the like, may not be performed.

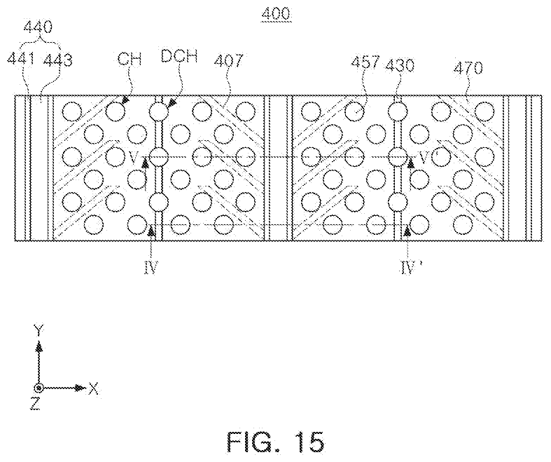

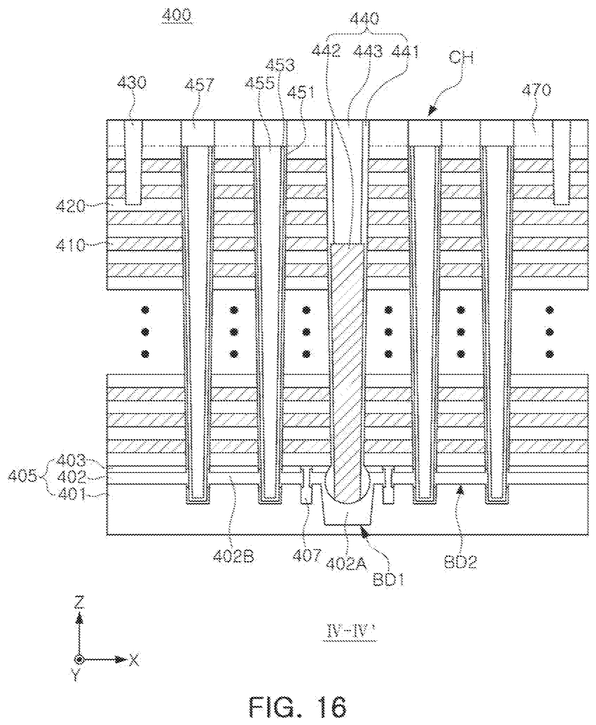

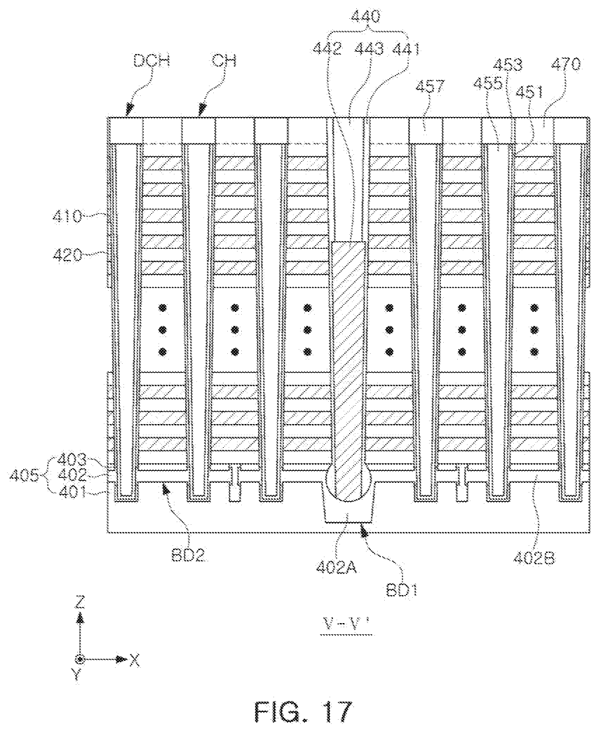

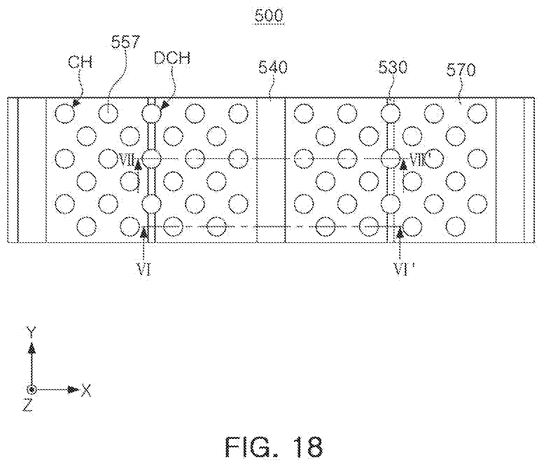

FIG. 15 is a plan view illustrating a portion of a memory device according to an example embodiment, FIG. 16 is a cross-sectional view taken along a line IV-IV′ in FIG. 14, and FIG. 17 is a cross-sectional view taken along a line V-V′ in FIG. 14.

Referring to FIGS. 15 to 17, a memory device 400 according to an example embodiment may include a substrate 405 including a first layer 401, a second layer 402, and a third layer 403 sequentially stacked, and the substrate 405 may be disposed on a base layer formed of an insulating material. Electrode layers 410 and insulating layers 420, channel structures CH, dummy channel structures DCH, upper separation layers 430, separation layers 440, interlayer insulating layer 470, and the like, may be provided on the substrate 405.

The second layer 402 may include a first region 402A, disposed below the separation layers 440 and having a relatively high thickness, and a second region 402B disposed between the channel structures CH and having a relatively small thickness. Due to such a difference in thickness, a boundary between the first layer 401 and the second layer 402 may include a first boundary BD1 and a second boundary BD2 disposed in different locations to each other in a first direction (a Z-axis direction). As an example, the first boundary BD1 may be disposed around the separation layers 440 and may be disposed to be lower than the second boundary BD2 between the channel structures CH.

Referring to FIGS. 15 to 17, the memory device 400 may include support patterns 407 for preventing the substrate 405 and/or a stacked structure on the substrate 405 from leaning during a manufacturing process. The support patterns 407 may be formed so as not to overlap with the channel structures CH. As an example, the support patterns 407 may extend in a diagonal direction intersecting a second direction (an X-axis direction) and a third direction (a Y-axis direction), as best seen in FIG. 15.

Each of the support patterns 407 may penetrate through the second layer 402. For example, the support patterns 407 may be in contact with the first layer 401 and the third layer 403. An upper surface of the support patterns 407 may be coplanar with an upper surface of the third layer 403, or may be embedded in the third layer 403 to be in contact with the third layer 403.

Referring to FIGS. 16 and 17, the separation layers 440 may include a side spacer 441, a lower separation conductive layer 442, an upper separation conductive layer 443, and the like. The lower separation conductive layer 442 and the upper separation conductive layer 443 may be formed of different conductive materials from each other. As an example, one of the lower separation conductive layer 442 and the upper separation conductive layer 443 may be formed of polysilicon, and the other may be formed of a metal such as tungsten, a metal compound, or the like. As illustrated in FIGS. 16 and 17, the lower separation conductive layer 442 and the upper separation conductive layer 443 may be formed of different materials from each other to address warpage which may occurs when a separation conductive layer is formed of a single material.

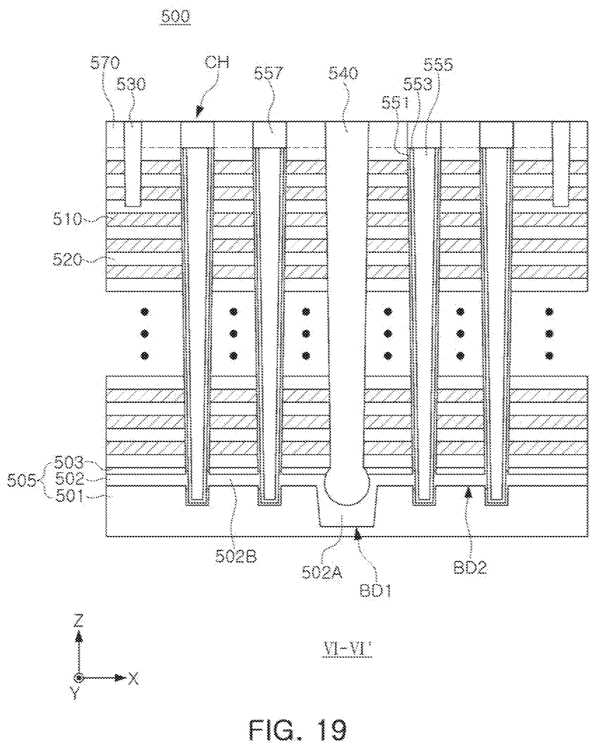

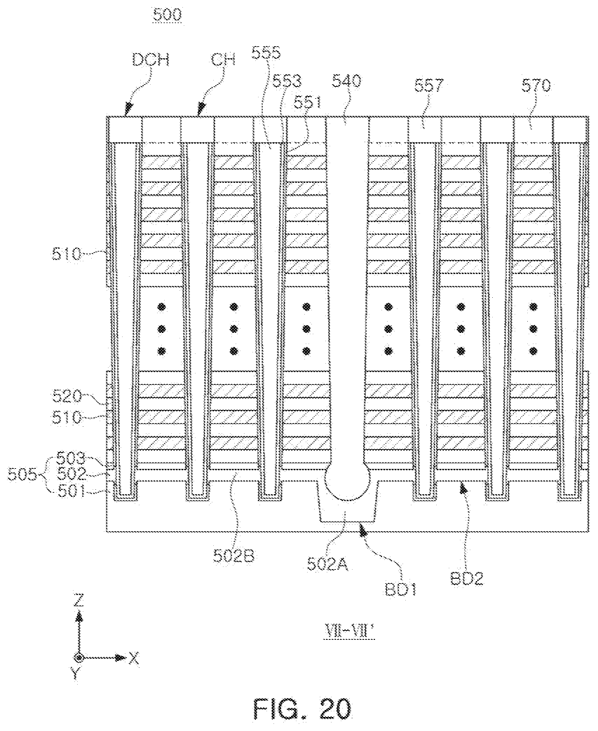

FIG. 18 is a plan view illustrating a portion of a memory device according to an example embodiment. FIG. 19 is a cross-sectional view taken along a line VI-VI′ in FIG. 18, and FIG. 20 is a cross-sectional view taken along a line VII-VII′ in FIG. 18.

Referring to FIGS. 18 to 20, a memory device 500 according to an example embodiment may include a substrate 505 including a first layer 501, a second layer 502, and a third layer 503 sequentially stacked, and the substrate 505 may be disposed on a base layer formed of an insulating material. Electrode layers 510 and insulating layers 520, channel structures CH, dummy channel structures DCH, upper separation layers 530, separation layers 540, and interlayer insulating layer 570, and the like, may be provided on the substrate 505.

The second layer 502 may include a first region 402A, disposed below the separation layers 540 and having a relatively high thickness, and a second region 402B disposed between the channel structures CH and having a relatively small thickness. Due to such a difference in thickness, a boundary between the first layer 501 and the second layer 502 may include a first boundary BD1 and a second boundary BD2 disposed in different locations to each other in a first direction (a Z-axis direction). As an example, the first boundary BD1 disposed around the separation layers 540 may be disposed to be lower than the second boundary BD2 between the channel structures CH.

In the example embodiment illustrated in FIGS. 18 to 20, additional support patterns may not be disposed. In the example embodiment illustrated in FIGS. 18 to 20, channel structures CH may prevent deformation of the electrode layers 510 and the insulating layers 520 during a manufacturing process while forming an empty space between the first layer 501 and the third layer 503 of the substrate 505. The support patterns may be omitted to decrease resistance of the substrate 505, especially the second layer 502, and to improve electrical characteristics of the memory device 500.

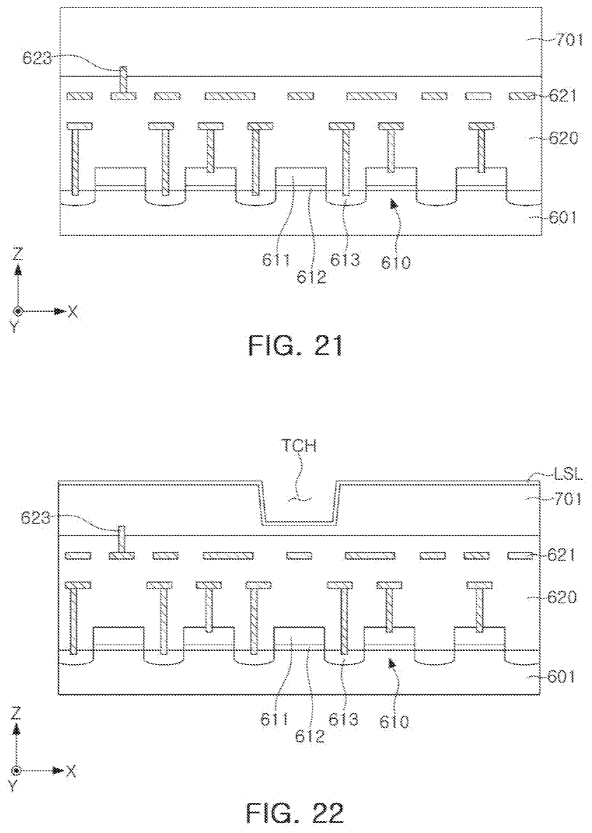

FIGS. 21 to 34 illustrate a method of manufacturing a memory device according to an example embodiment.

Referring to FIG. 21, a method of manufacturing a memory device according to an example embodiment may start with formation of a first layer 701 for forming a substrate on a base layer 620. A memory device, manufactured according to the method described with reference to FIGS. 21 to 34, may have a cell-on-peri (COP) structure in which peripheral circuit regions and cell regions are stacked in a first direction (a Z-axis direction). In example embodiments, the first layer 701 may be formed of a first material different from a material of the base layer 620. As an example, the first material may be a semiconductor material or polysilicon doped with n-type impurities. In the case in which the memory device does not have a COP structure, the first layer 701 may be formed without an additional base layer 620 by implanting impurities into a semiconductor wafer.

In the example embodiment illustrated in FIG. 21, the base layer 620 may be a lower interlayer insulating layer, included in a peripheral circuit region, and may be formed on a lower substrate 601 to cover circuit elements 610 and metal wirings 621. Each of the circuit elements 610 may include a gate electrode 611, an electrode insulating layer 612, a source/drain region 613, and the like, and may provide circuits required to drive the memory device. At least a portion of the metal wirings 621 may be electrically connected to the first layer 701 by a source contact 623.

Referring to FIG. 22, a portion of the first layer 701 may be removed to form trenches TCH. The trenches TCH may extend in a third direction (a Y-axis direction) and may be separated from each other in a second direction (an X-axis direction). When the trenches TCH are formed, a lower sacrificial layer LSL may be formed on an upper surface of the first layer 701. The lower sacrificial layer LSL may be formed of an insulating material, for example, a silicon oxide, and may be conformally formed to cover the upper surface and internal side surfaces and lower surfaces of the trenches TCH. As an example, the trenches TCH may be formed to correspond to a region in which separation layers are to be formed in a subsequent process.

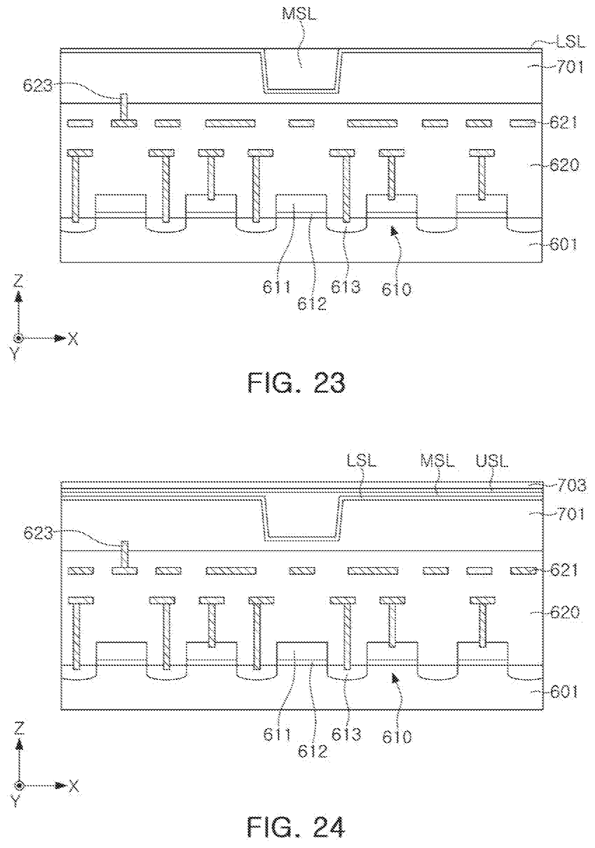

Referring to FIG. 23, an intermediate sacrificial layer MSL may be formed to fill the trenches TCH. In the example embodiment illustrated in FIG. 23, the intermediate sacrificial layer MSL may be formed of a second material different from a material of the base layer 620. As an example, the second material may be polysilicon, and may be doped with n-type impurities. When the trenches TCH are filled, the intermediate sacrificial layer MSL, the upper sacrificial layer USL, and a stopper layer 703 may be continuously formed, as illustrated in FIG. 24. In example embodiments, the stopper layer 703 may be formed of a semiconductor material, and may or may not be doped with n-type impurities according to example embodiments. The stopper layer 703 may have a lower impurity concentration than the first layer 701. An upper sacrificial layer USL may be formed of the same insulating material as the lower sacrificial layer LSL.

The stopper layer 703 may have a thickness of tens of nanometers, for example, 30 nanometers or less. The thickness of the stopper layer 703 may be less than a sum of thicknesses of the upper sacrificial layer USL, the lower sacrificial layer LSL, and the intermediate sacrificial layer MSL. In a region in which the trenches TCH are not formed, the first layer 701 may have a thickness of hundreds of nanometers to 1000 nanometers. The trenches TCH are formed such that the first layer 701 is not completely removed. Accordingly, a depth of the trenches TCH may be less than the thickness of the first layer 701. In example embodiments, the thicknesses of the upper sacrificial layer USL and the lower sacrificial layer LSL may be substantially the same.

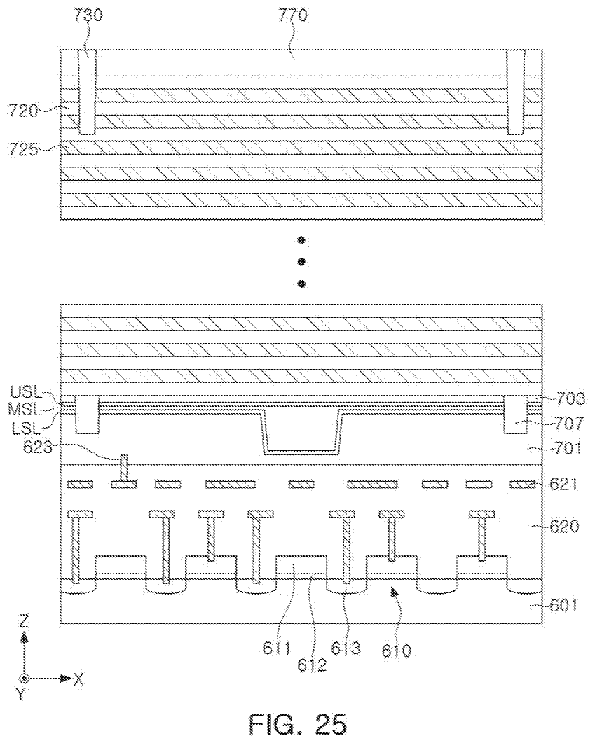

Referring to FIG. 25, support patterns 707 may be formed to be in contact with the first layer 701 through the stopper layer 703, the upper sacrificial layer USL, the intermediate sacrificial layer MSL, the lower sacrificial layer LSL. The support patterns 707 may be separated from each other in the second direction and the third direction, as described above. In the example embodiment illustrated in FIG. 25, upper surfaces of the support patterns 707 may be coplanar with an upper surface of the stopper layer 703. The support patterns 707 may have a tapered shape in which widths thereof are decreased in a direction toward the base layer 620. The support patterns 707 may be disposed in a region in which channel structures are not to be formed in a subsequent process.

When the support patterns 707 are formed, the insulating layers 720 and the electrode sacrificial layers 725 may be alternately stacked on the stopper layer 703. The insulating layers 720 and the electrode sacrificial layers 725 may be formed of a material having a predetermined etching selectivity. As an example, the insulating layers 720 may be formed of a silicon oxide, the electrode sacrificial layers 725 may be formed of a silicon nitride, and the insulating layers 720 may not be removed while the electrode sacrificial layers 725 are removed by an etching process. The interlayer insulating layer 770 may be formed on the insulating layers 720 and the electrode sacrificial layers 725, and may be formed of the same material as the insulating layers 720. In example embodiments, before the interlayer insulating layer 770 is formed, the insulating layers 720 and the electrode sacrificial layers 725 may be etched to form staircase-shaped pad regions.

When the interlayer insulating layer 770 is formed, upper separation layers 730 may be formed to divide a portion of the electrode sacrificial layers 725 into a plurality of regions. Upper separation layers 730 may be formed of the same material as the insulating layers 720. In the example embodiment illustrated in FIG. 25, the upper separation layers 730 are illustrated as being formed respectively on the support patterns 707. However, the present disclosure is not limited thereto. The upper separation layers 730 may not be disposed respectively above the support patterns 707, depending on the arrangement of the support patterns 707.

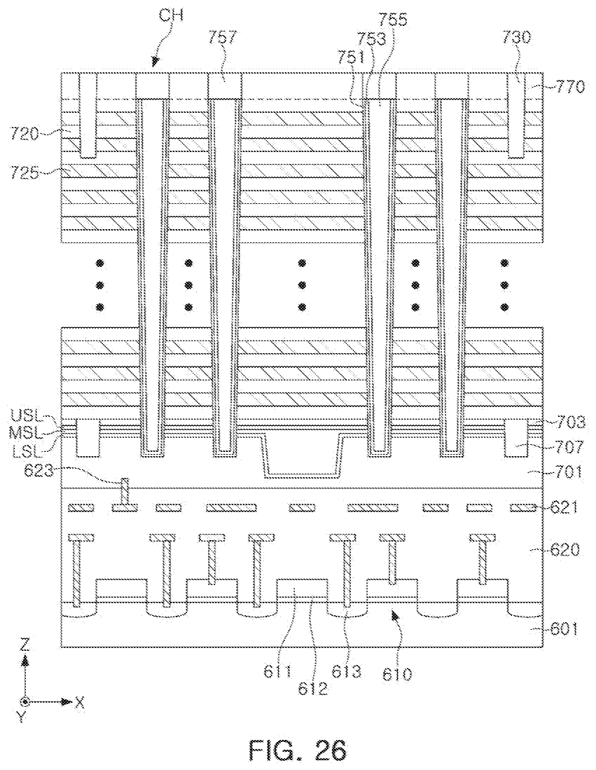

Referring to FIG. 26, channel structures CH may be formed to penetrate through the insulating layers 720, the electrode sacrificial layers 725, and the interlayer insulating layer 770. Each of the channel structures CH may include an electrode insulating layer 751, a channel layer 753, a buried insulating layer 755, and a channel connection layer 757. The electrode insulating layer 751 may include a plurality of layers, for example, a blocking layer, a charge storage layer, a tunneling layer, and the like, and at least a portion of the plurality of layers may be formed of different materials to each other. The channel layer 753 may be formed of polysilicon doped with impurities, or the like. The buried insulating layer 755 may fill an internal space of the channel layer 753. The channel connection layer 757 may be formed of doped polysilicon, or the like. As an example, the channel layer 753 and the channel connection layer 757 may be doped with impurities of different conductivity types.

The channel structures CH may extend to the first layer 701 of the substrate 705. Therefore, the electrode insulating layer 751 may be in contact with a lower sacrificial layer LSL, an intermediate sacrificial layer MSL, an upper sacrificial layer USL, a stopper layer 703, and a first layer 701, as illustrated in FIG. 26. In FIG. 26, lower surfaces of the channel structures CH are illustrated as being disposed at substantially the same height as lower surfaces of the support patterns 707. However, the present disclosure is not limited thereto. The lower surfaces of the channel structures CH may be disposed to be higher or lower than the lower surfaces of the support patterns 707.

As described with reference to FIG. 22, a lower surface of the lower sacrificial layer LSL, formed in the trenches TCH of the first layer 701, may be disposed to be lower than the lower surfaces of the channel structures CH. However, this is only an example, and the lower surface of the lower sacrificial layer LSL formed in the trenches TCH may be disposed to be higher than the lower surfaces of the channel structures CH, or may be disposed at the substantially the same as the lower surface of the channel structures CH.

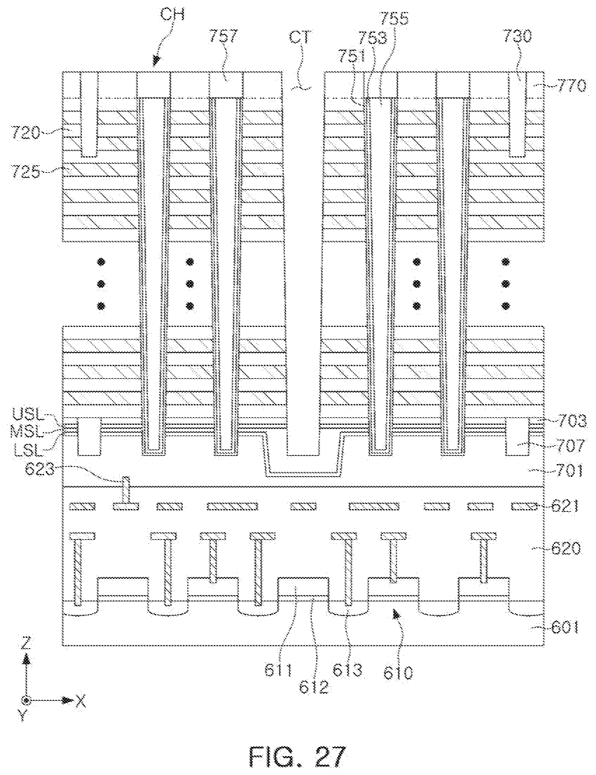

Referring to FIG. 27, separation trenches CT may be formed to divide the insulating layers 720 and the electrode sacrificial layers 725 into a plurality of unit structures. As an example, each of the unit structures may be a memory block. The separation trenches CT may be formed to penetrate into the substrate 705 by a predetermined depth. As an example, the intermediate sacrificial layer MSL may be exposed by the separation trenches CT.

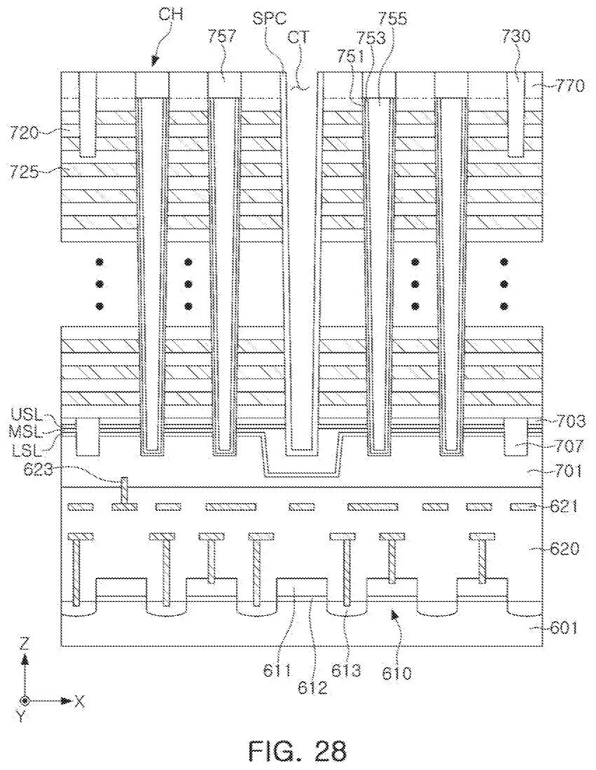

Referring to FIG. 28, the lower surfaces of the separation trenches CT may be disposed between the upper sacrificial layer USL and the lower sacrificial layer LSL. Accordingly, the intermediate sacrificial layer MSL may be exposed. This may be aimed at facilitating removal of the intermediate sacrificial layer MSL, the upper sacrificial layer USL, and the lower sacrificial layer LSL in a subsequent process. In example embodiments, as described above with reference to FIGS. 22 and 23, trenches TCH may be formed in the first layer 701 in advance and the trenches TCH may be filled with the intermediate sacrificial layer MSL. The trenches TCH may be disposed below a region in which the separation trenches CT are respectively formed. Accordingly, the intermediate sacrificial layer MSL having a relatively high thickness below the separation trenches CT may be secured, and a process of forming the separation trenches CT to expose the intermediate sacrificial layer MSL may be easily performed by increasing a margin of an etching process.

Referring to FIG. 28, a spacer layer SPC may be formed in the separation trenches CT. The spacer layer SPC may be conformally formed in the separation trenches CT, and may be formed of a material different from materials of the upper sacrificial layer USL, the intermediate sacrificial layer MSL, and the lower sacrificial layer LSL. As an example, the spacer layer SPC may be formed of a silicon nitride.

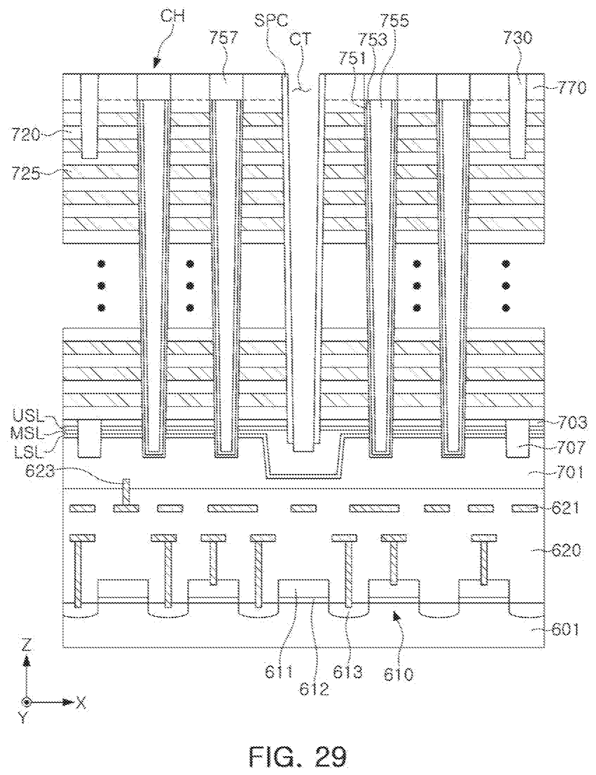

Referring to FIG. 29, an etch-back process may be performed such that the spacer layers SPC, formed on lower surfaces of the separation trenches CT, are selectively removed to re-expose the intermediate sacrificial layer MSL. After the etch-back process, the spacer layer SPC may remain on side surfaces of the separation trenches CT, and a lower surface of the spacer layer SPC may be disposed in the intermediate sacrificial layer MSL.

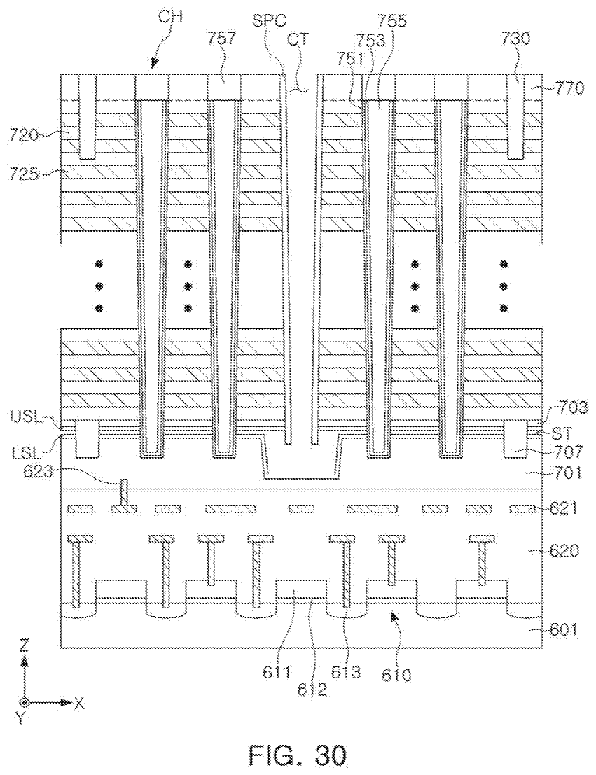

Referring to FIG. 30, an etching process may be performed through the separation trenches CT to remove the intermediate sacrificial layer MSL. As described above, the sacrificial layer MSL may be formed of polysilicon. Therefore, the spacer layer SPC may not be removed during removal of the intermediate sacrificial layer MSL, and the sacrificial layers 720 and the insulating layers 725 may be protected from the etching process. The intermediate sacrificial layer MLS may be removed to form a horizontal trench ST.

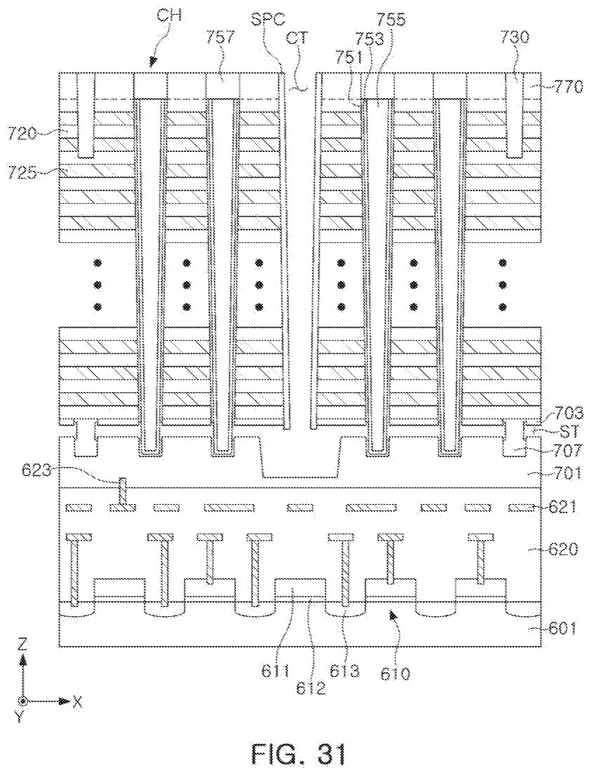

Referring to FIG. 31, an additional etching process may be performed through separation trenches CT. The upper sacrificial layer USL and the lower sacrificial layer LSL exposed in the horizontal trench ST may be removed by an etching process described with reference to FIG. 31. In addition, a portion of the electrode insulating layer 751 and the support pattern 707 may be removed together with the upper sacrificial layer USL and the lower sacrificial layer LSL.

Referring to FIGS. 30 and 31, as the upper sacrificial layer USL, the intermediate sacrificial layer MSL, and the lower sacrificial layer LSL are removed by the etching process, the first layer 701 and the stopper layer 703 of the substrate 705 may be separated from each other in a first direction. Removal of the intermediate sacrificial layer MSL may be followed by removal of the upper sacrificial layer USL and lower sacrificial layer LSL. In addition, since the insulating layers 720, the sacrificial layers 725, and the interlayer insulating layer 770 are stacked on the stopper layer 703, the stopper layer 703 may lean due to a weight applied to the stopper layer 703.

In example embodiments, a load applied to the stopper layer 703 may be born with the channel structures CH. Alternatively, support patterns 707 may be disposed to distribute a load applied to the stopper layer 703. Since the support patterns 707 extend from the stopper layer 703 to the first layer 701, leaning of the stopper layer 703, caused by the horizontal trench ST, may be prevented.

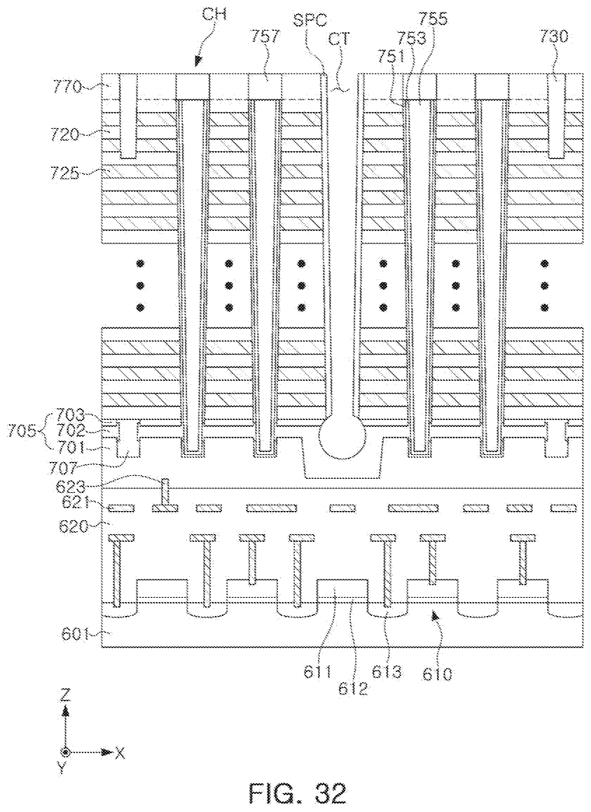

Referring to FIG. 32, the horizontal trench ST may be filled. The horizontal trench ST may be filled with a semiconductor material. The semiconductor material, filling the horizontal trench ST, may be polysilicon, for example, polysilicon doped with n-type impurities. The horizontal trench ST may be filled with a semiconductor material to form a substrate 705, as illustrated in FIG. 32. The substrate 705 may include a first layer 701, a second layer 702 provided by the semiconductor material filling the horizontal trench ST, and a third layer 703 provided by the stopper layer 703. Since the channel layers 753 of the channel structures CH are exposed to an external entity in the horizontal trench ST by the previously performed etching process, the channel layers 753 may be electrically connected to each other by the second layer 702.

The semiconductor material, filling the horizontal trench ST, may be introduced through the separation trenches CT. Therefore, a lower surface of the separation trench ST may have a curved shape, as illustrated in FIG. 32. However, this is just an example and the lower surface of the separation trench ST may be changed to have various shapes according to example embodiments.

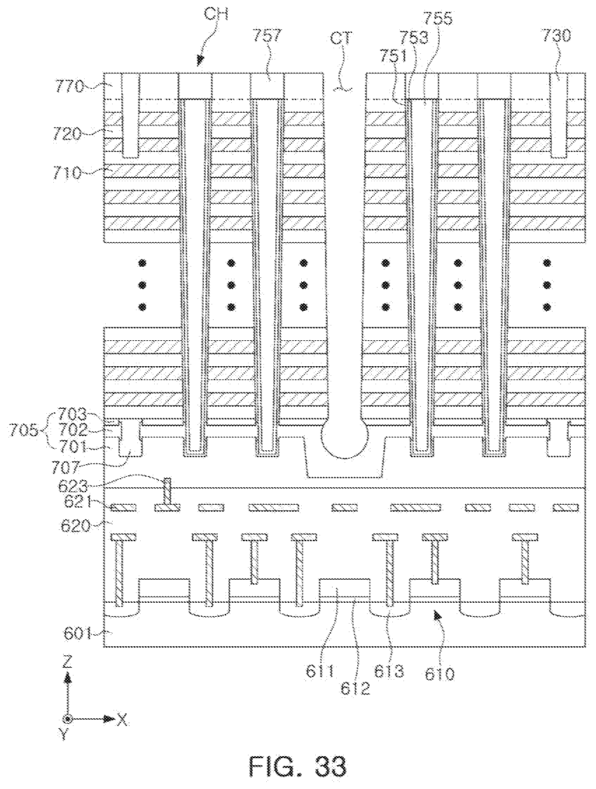

Referring to FIG. 33, after removing the spacer layer SPC and the electrode sacrificial layers 725 in the separation trenches CT, the electrode layers 710 may be formed. As described above, due to the etching selectivity, the insulating layers 720 may not be removed while removing the electrode sacrificial layers 725. When the spacer layer SPC and the electrode sacrificial layers 725 are formed of the same material, the spacer layer SPC and the electrode sacrificial layers 725 may be removed by the same etching process. As an example, the spacer layer SPC and the electrode sacrificial layers 725 may be removed by performing an etching process once.

The electrode layers 710 may include a conductive material, for example, a metal, a metal compound, or the like. The electrode layers 710 may be in contact with the electrode insulating layer 751 of the channel structures CH, and may be provided as wordlines for driving memory cells.

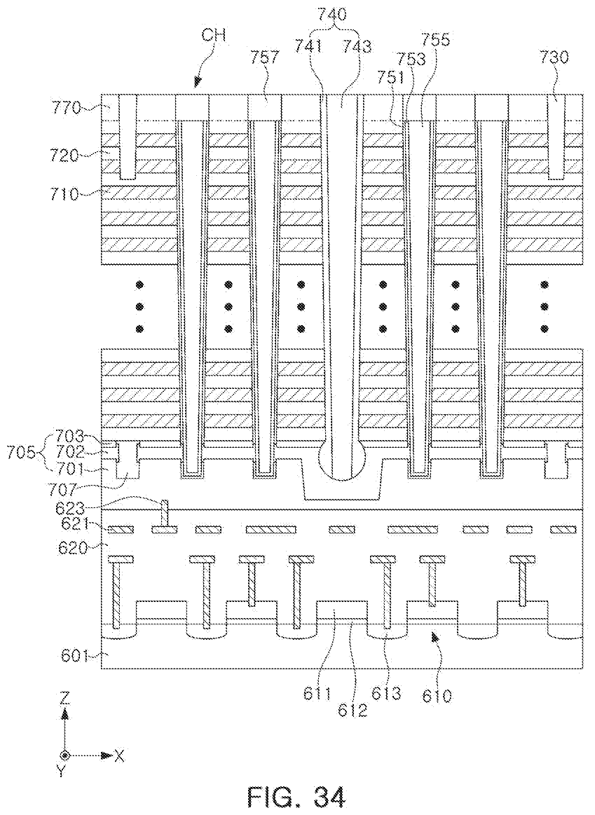

Referring to FIG. 34, a side spacer 741 and a separation conductive layer 743 may be formed in the separation trenches CT. The side spacers 741 and the separation conductive layer 743 may provide a separation layer 740. The separation conductive layer 743 may be connected to the second layer 702 of the substrate 705, or the like, and may reduce resistance of the substrate 705. According to example embodiments, the separation conductive layer 743 may be omitted, or the separation conductive layer 743 may include a plurality of layers formed of different conductive materials to each other.

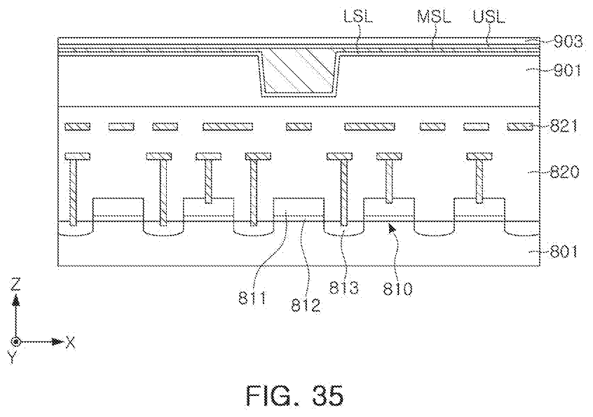

FIGS. 35 to 41 illustrate a method of manufacturing a memory device according to an example embodiment.

A memory device, manufactured according to the method described with reference to FIGS. 35 to 41, may have a cell-on-peri (COP) structure in which peripheral circuit regions and cell regions are stacked in a first direction (a Z-axis direction). In example embodiments, a first layer 901 may be formed of polysilicon doped with n-type impurities. In the case in which the memory device does not have a COP structure, the first layer 901 may be formed without an additional base layer 820 by implanting impurities into a semiconductor wafer.

The base layer 820 may be a lower interlayer insulating layer included in a peripheral circuit region, and may be formed on a lower substrate 801 to cover circuit elements 810 and metal wirings 821. Each of the circuit elements 810 includes a gate electrode 811, an electrode insulating layer 812, a source/drain region 813, and the like, and may provide circuits required to drive a memory device.

A lower sacrificial layer LSL, an intermediate sacrificial layer MSL, an upper sacrificial layer USL, and a stopper layer 903 may be sequentially stacked on the first layer 901. As an example, a portion of the first layer 901 may be selectively removed and a space, in which the portion of the first layer 901 is removed, may be filled with the lower sacrificial layer LSL and the intermediate sacrificial layer MSL.

In the example embodiment illustrated in FIG. 35, the lower sacrificial layer LSL and the upper sacrificial layer USL may be formed of the same insulating material, and the intermediate sacrificial layer MSL may be formed of a material different from the material of the lower sacrificial layer LSL and the upper sacrificial layer USL. As an example, the lower sacrificial layer LSL and the upper sacrificial layer USL may be formed of a silicon oxide, and the intermediate sacrificial layer MSL may be formed of a silicon nitride. The stopper layer 703 may be formed of polysilicon.

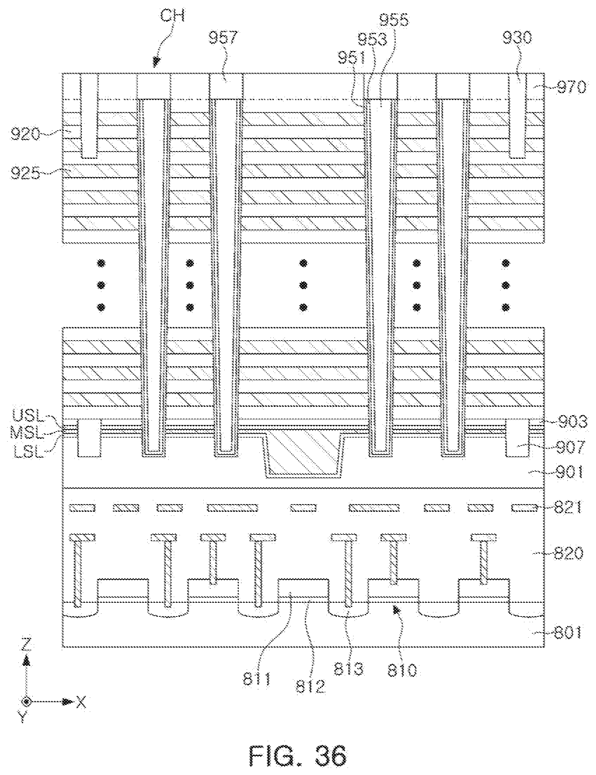

Referring to FIG. 36, support patterns 907 may be formed to extend from the stopper layer 903 to the first layer 901. The support patterns 907 may penetrate through the lower sacrificial layer LSL, the intermediate sacrificial layer MSL, and the upper sacrificial layer USL. In addition, insulating layers 920 and electrode sacrificial layers 925 may be alternately stacked on the stopper layer 903. The insulating layers 920 and the electrode sacrificial layers 925 may be formed of a material having predetermined etch selectivity. An interlayer insulating layer 970 may be formed on the insulating layers 920 and the electrode sacrificial layers 925, and channel structures CH may be formed to penetrate through the insulating layers 920, the electrode sacrificial layers 925, and the interlayer insulating layer 970 Structures CH may be formed.

Each of the channel structures CH may include an electrode insulating layer 951, a channel layer 953, a buried insulating layer 955, a channel connection layer 957, and the like. The channel structures CH may be understood based on the example embodiment described with reference to FIG. 25. Upper separation layers 930 may be formed on the support patterns 907, and a portion of the electrode sacrificial layers 925 may be divided into a plurality of regions by the upper separation layers 930.

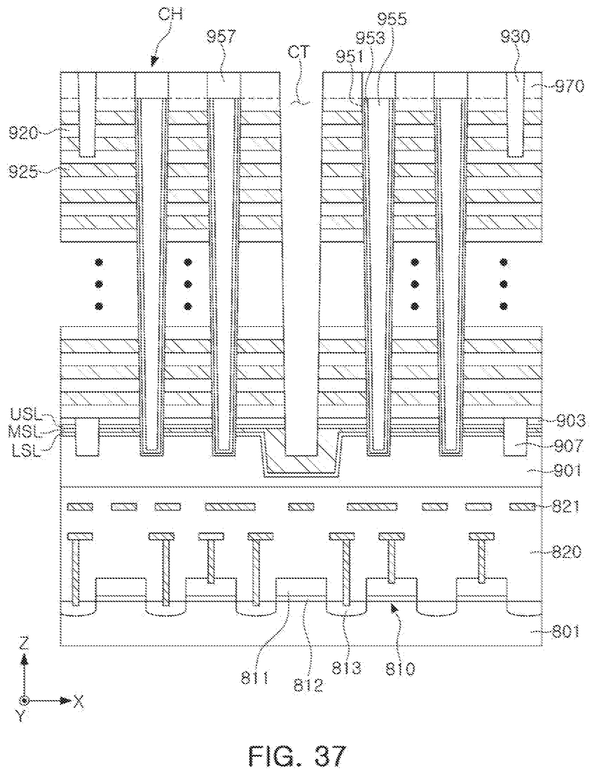

Referring to FIG. 37, separation trenches CT may be formed. The separation trenches CT may divide the insulating layers 920 and the electrode sacrificial layers 925 into a plurality of unit structures. In example embodiments, the unit structures may be memory blocks. The intermediate sacrificial layer MSL may be exposed to an external entity by the separation trenches CT. The intermediate sacrificial layer MSL may be formed to have a relatively high thickness below a region, in which the separation trenches CT are to be formed, such that an etching process for forming the separation trenches CT may be easily performed.

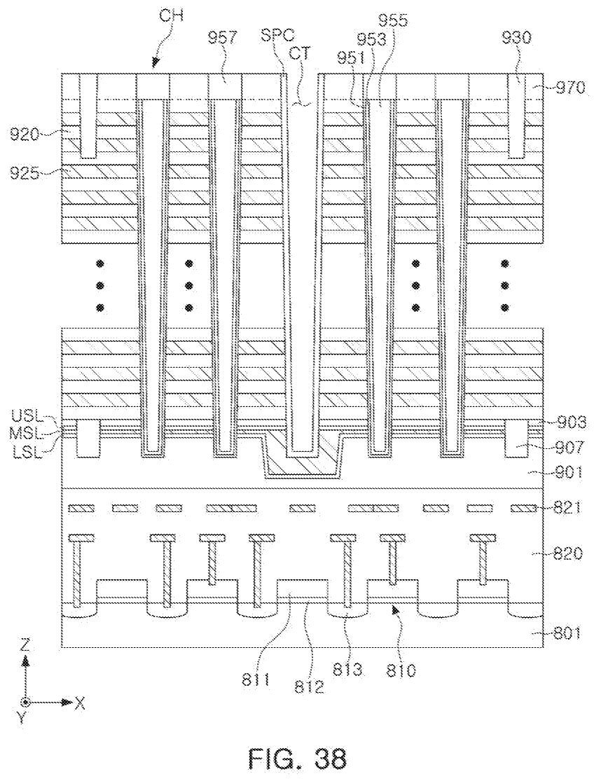

Referring to FIG. 38, a spacer layer SPC may be formed in the separation trenches CT. After formation of the spacer layer SPC, an etch-back process may be performed to re-expose the intermediate sacrificial layer MSL on lower surfaces of the separation trenches CT. In the example embodiment illustrated in FIG. 38, the spacer layer SPC may be formed of amorphous silicon, polysilicon, or the like. Alternatively, polysilicon may be conformally formed in the separation trenches CT and a portion of the polysilicon may then be oxidized to form a spacer layer SPC having a structure including two or more layers.

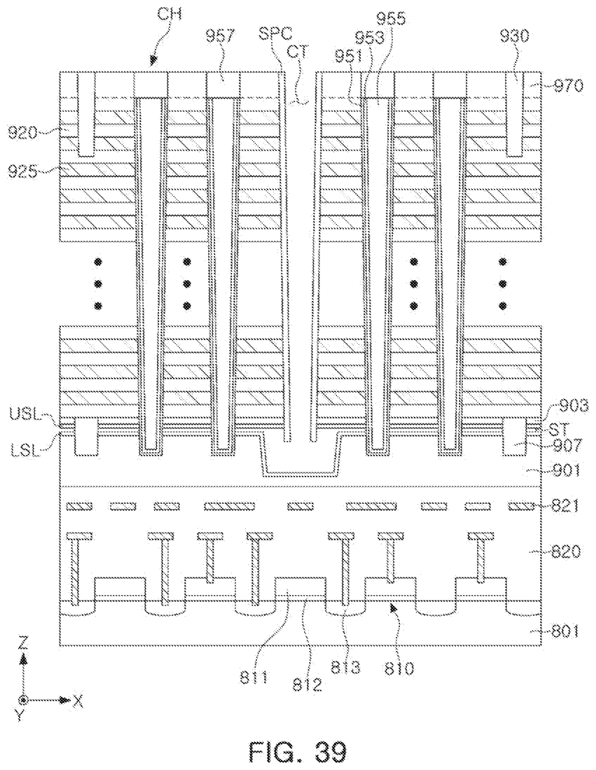

Referring to FIG. 39, the intermediate sacrificial layer MSL may be removed through the separation trenches CT to form a horizontal trench ST. While the horizontal trench ST is present, the channel structures CH and the support patterns 907 may support a load of the stopper layer 903 and the upper sacrificial layer USL. Since the intermediate sacrificial layer MSL is formed of a silicon nitride, the spacer layer SPC formed of amorphous silicon, polysilicon, oxide, or the like, may not be removed and the insulating layers 920 and the electrode sacrificial layers 925 may be protected during removal of the intermediate sacrificial layer MSL.

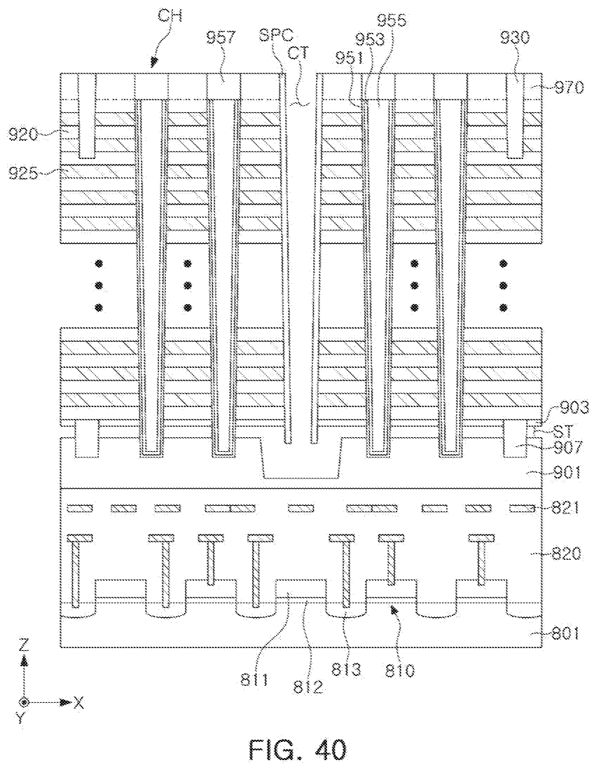

Referring to FIG. 40, an additional etching process may be performed in the horizontal trench ST to remove a portion the electrode insulating layer 951 and a portion the support pattern 907 in the horizontal trench ST together with the exposed upper sacrificial layer USL and the exposed lower sacrificial layer LSL. As illustrated in FIG. 40, a semiconductor material may fill the extending horizontal trench ST.

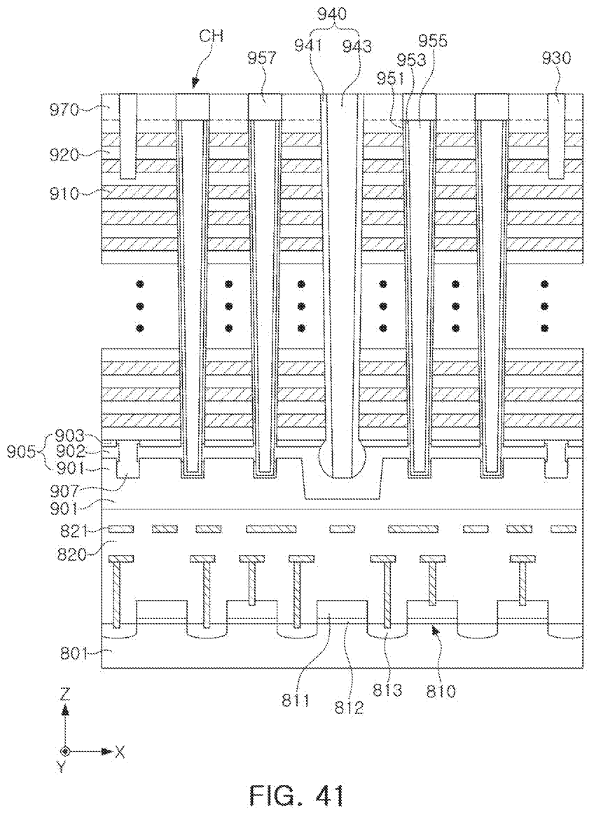

Therefore, as illustrated in FIG. 41, a substrate 905 having a first layer 901, a second layer 902, and a third layer 903 may be formed. A thickness of the third layer 903 may be smaller than a thickness of the first layer 901 and a thickness of the second layer 902. When the substrate 905 is formed, the spacer layer SPC may be removed to expose the sacrificial layers 925 on side surfaces of the separation trenches CT. The electrode sacrificial layers 925 may be selectively removed and then filled with a conductive material to form electrode layers 910. When the electrode layers 910 are formed, a side spacers 941 and a separation conductive layer 943 may be formed in the separation trenches CT to form a separation layer 940.

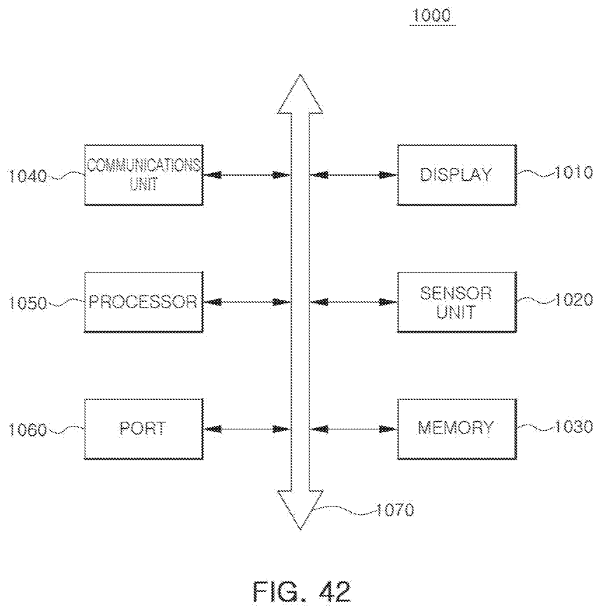

FIG. 42 is a schematic block diagram of an electronic device including a memory device according to an example embodiment.

An electronic device 1000 according to an example embodiment illustrated in FIG. 42 may include a display 1010, a sensor unit 1020, a memory 1030, a communications unit 1040, a processor 1050, a port 1060, and the like. The electronic device 1000 may further include a power supply, an input/output device, and the like. Among the components illustrated in FIG. 42, the port 1060 may be a device provided for the electronic device 1000 to communicate with a video card, a sound card, a memory card, a universal serial bus (USB) device, and the like. The electronic device 1000 may be a comprehensive concept including a smartphone, a tablet personal computer (PC), a smart wearable device, and the like, as well as a general desktop PC and a laptop PC.

The processor 1050 may execute a specific operation or an instruction, a task, and the like. The processor 1050 may be a central processing unit (CPU), a microprocessor unit (MCU), a system on chip (SoC), or the like, and may communicate with the display 1010, the sensor unit 1020, the memory 1030, the communications unit 1040, and other devices connected to the port 1060, via a bus 1070.

The memory 1030 may be a storage medium configured to store data necessary for the operation of the electronic device 1000, or multimedia data. The memory 1030 may include a volatile memory such as a random access memory (RAM) or a nonvolatile memory such as a flash memory. In addition, the memory 1030 may include at least one of a solid state drive (SSD), a hard disk drive (HDD), and an optical disk drive (ODD), as a storage device. In the example embodiment illustrated in FIG. 42, the memory 1030 may include memory devices according to various embodiments described with reference to FIGS. 1 to 41.

As described above, a substrate may include a first layer and a second layer, and the second layer may be connected to side surfaces of channel layers. Also, the second layer may have a relatively greater thickness below a separation layer. Difficulty of an etching process for forming the second layer may be lowered, and reliability of a memory device may be improved.

While example embodiments have been shown and described above, it will be apparent to those skilled in the art that modifications and variations could be made without departing from the scope of the present inventive concept as defined by the appended claims.

1. A memory device comprising:
a substrate including a first layer, a second layer on the first layer, and a third layer on the second layer;
a stacked structure including a plurality of electrode layers stacked on the substrate;
a plurality of channel layers extending in a direction perpendicular to an upper surface of the substrate, to penetrate through the stacked structure and to contact with the second layer in a direction horizontal to the upper surface of the substrate; and
a plurality of separation layers dividing the stacked structure into unit structures,
wherein a first boundary between the first layer and the second layer below at least one of the plurality of separation layers is disposed to be lower than a second boundary between the first layer and the second layer that is located between an adjacent two channel layers of the plurality of channel layers.

2. The memory device of claim 1, wherein the first boundary is disposed to be lower than lower surfaces of the plurality of channel layers.

3. The memory device of claim 1, wherein a thickness of the first layer below at least one of the plurality of separation layers is smaller than a thickness of the first layer below at least one of the plurality of channel layers.

4. The memory device of claim 1, further comprising:
a plurality of support patterns disposed between adjacent ones of at least a portion of the plurality of channel layers, each of the plurality of support patterns extending from an upper surface of the third layer to the first layer.

5. The memory device of claim 4, wherein at least one of the plurality of support patterns includes a first support region in contact with the first layer, and a second support region in contact with the second layer, and
a width of the first support region is greater than a width of the second support region.

6. The memory device of claim 5, wherein the at least one of the plurality of support patterns includes a third support region in contact with the third layer, and
a width of the third support region is greater than a width of the second support region.

7. The memory device of claim 4, wherein the first boundary is disposed to be lower than lower surfaces of the plurality of support patterns.

8. (canceled)

9. The memory device of claim 4, wherein the plurality of support patterns are disposed respectively below a plurality of upper separation layers that extend in the direction perpendicular to the upper surface of the substrate and divide a portion the plurality of electrode layers, and
the plurality of support patterns are separated from each other in a first direction parallel to the upper surface of the substrate.

10. The memory device of claim 1, wherein the first layer and the second layer include impurities of a same conductivity type.

11. The memory device of claim 1, wherein an impurity concentration of the third layer is lower than an impurity concentration of the first layer and lower than an impurity concentration of the second layer.

12. The memory device of claim 1, wherein a thickness of the third layer is smaller than a thickness of the first layer and smaller than a thickness of the second layer.

13. The memory device of claim 1, further comprising:
a base layer in contact with a lower surface of the first layer and including an insulating material;
a plurality of circuit elements disposed below the base layer; and
a source contact that penetrates through the base layer and electrically connects at least one of the plurality of circuit elements to the first layer.

14. A memory device comprising:
a substrate including a first layer, a second layer, and a third layer sequentially stacked;
a plurality of channel layers extending in a first direction perpendicular to an upper surface of the substrate, extending to the first layer through the second layer and the third layer, and being in contact with the second layer in a direction parallel to the upper surface of the substrate;
a plurality of electrode layers stacked on the upper surface of the substrate; and
a plurality of separation layers extending between the plurality of channel layers in the first direction and extending in a second direction parallel to the upper surface of the substrate,
wherein a portion of a lower surface of the second layer, being in contact with the first layer, is disposed to be lower than lower surfaces of the plurality of channel layers, and a remaining portion of the lower surface of the second layer is disposed to be higher than the lower surfaces of the plurality of channel layers.

15. The memory device of claim 14, wherein a first portion of the lower surface of the second layer that is disposed below at least one of the plurality of separation layers is disposed to be lower than the lower surfaces of the plurality of channel layers.

16. The memory device of claim 14, wherein a first portion of the lower surface of the second layer that is disposed below at least one of the plurality of separation layers is disposed to be higher than the lower surfaces of the plurality of channel layers.

17-18. (canceled)

19. The memory device of claim 14, wherein a thickness of the third layer is smaller than a thickness of the second layer.

20. The memory device of claim 14, wherein a thickness of the first layer is greater than a thickness of the third layer below the plurality of separation layers.

21-23. (canceled)

24. A memory device comprising:
a peripheral circuit region including a lower substrate, a plurality of circuit elements disposed on the lower substrate, and a lower interlayer insulating layer covering the plurality of circuit elements; and
a cell region including an upper substrate disposed on the lower interlayer insulating layer, a plurality of electrode layers stacked in a first direction perpendicular to an upper surface of the upper substrate, a plurality of channel layers extending in the first direction to penetrate through the plurality of electrode layers and electrically connected to the upper substrate, and a separation layer dividing the plurality of electrode layers,
wherein the upper substrate includes a first layer, a second layer that is stacked on the first layer and that is in contact with the plurality of channel layers in a direction parallel to an upper surface of the first layer, and a third layer that is stacked on the second layer, and
the second layer includes a first region below the separation layer and a second region between the plurality of channel layers, and a thickness of the first region is greater than a thickness of the second region.

25. The memory device of claim 24, wherein the second layer is in contact with channel layers of the plurality of channel layers that are disposed on respective sides of the separation layer.

26. The memory device of claim 25, wherein a lower surface of the separation layer is disposed to be higher than a lower surface of the first region.

27-37. (canceled)
